(19) United States
(12) Patent Application Publication
(10) Pub. No.: US 2011/0053092 A1
(43) Pub. Date: Mar. 3, 2011

(54) OBJECT PROCESSING APPARATUS, EXPOSURE APPARATUS AND EXPOSURE METHOD, AND DEVICE MANUFACTURING METHOD

(75) Inventor: Yasuo AOKI, Zushi-shi (JP)

(73) Assignee: NIKON CORPORATION, Tokyo (JP)

(21) Appl. No.: 12/859,484

(22) Filed: Aug. 19, 2010

Related U.S. Application Data
(60) Provisional application No. 61/272,320, filed on Sep. 10, 2009.

(30) Foreign Application Priority Data
Aug. 20, 2009 (JP) 2009-190654

(51) Int. Cl. G03B 27/58; G03F 7/20; B23Q 16/00; B25B 11/00

(52) U.S. Cl. 430/319; 355/72; 355/77; 430/325; 269/56; 269/21

(57) ABSTRACT

A plurality of air levitation units that jet air to the lower surface of a substrate are placed below the substrate, and the substrate is supported in a noncontact manner so as to be substantially horizontal. Further, a portion subject to exposure of the substrate is held from below in a noncontact manner by a chuck main body that a fixed-point stage has, and a surface position of the portion subject to exposure is adjusted in a pinpoint manner. Consequently, exposure can be performed on the substrate with high precision. Since the chuck main body moves in a scanning direction according to the position of the substrate, the chuck main body can surely hold the substrate even when the substrate proceeds into an exposure area.

### CROSS-REFERENCE TO RELATED APPLICATIONS

This non-provisional application claims the benefit of Provisional Application No. 61/272,320 filed Sep. 10, 2009, the disclosure of which is hereby incorporated herein by reference in its entirety.

### BACKGROUND OF THE INVENTION

1. Field of the Invention

The present invention relates to object processing apparatuses, exposure apparatuses and exposure methods, and device manufacturing methods, and more particularly to an object processing apparatus that performs predetermined processing to a tabular object placed along a predetermined two-dimensional plane, an exposure apparatus and an exposure method to expose the object, and a device manufacturing method that uses the exposure apparatus or the exposure method.

2. Description of the Background Art

Conventionally, in a lithography process for manufacturing electron devices (microdevices) such as liquid crystal display elements or semiconductor devices (integrated circuits or the like), an exposure apparatus such as a projection exposure apparatus by a step-and-repeat method (a so-called stepper), or a projection exposure apparatus by a step-and-scan method (a so-called scanning stepper (which is also called a scanner)) is mainly used.

In this type of the exposure apparatus, as an exposure subject, a substrate such as a glass plate or a wafer whose surface is coated with a photosensitive agent (hereinafter, generically referred to as a substrate) is mounted on a substrate stage device. And, exposure light is irradiated on a mask (or a reticle) on which a circuit pattern is formed, and the exposure light via the mask is irradiated on the substrate via an optical system such a projection lens, and thereby the circuit pattern is transferred onto the substrate (e.g., refer to PCT International. Publication No. 2008/129762 (and the corresponding U.S. Patent Application Publication No. 2010/0018950)).

In recent years, however, a substrate that is an exposure subject of an exposure apparatus, especially, a substrate for liquid crystal display element (a rectangular glass substrate) has tended to grow in size, for example, the length of a side of the substrate has been increased to 3 m or more, and accordingly, the size of a stage device of the exposure apparatus has increased, and the weight has also increased. Therefore, the development of a stage device has been desired that can guide an exposure subject (substrate) at a high speed and with high precision and, further, has a simple configuration with which the size and weight can be reduced.

### SUMMARY OF THE INVENTION

According to a first aspect of the present invention, there is provided an object processing apparatus, comprising: an object driving device that drives a tabular object placed along a predetermined two-dimensional plane that is parallel to a horizontal plane, in at least one axis direction within the two-dimensional plane; an executing device that, with respect to the object that is driven at a constant speed by the object driving device, executes predetermined processing on a portion subject to processing of a surface of the object, within a predetermined area in a movement course of the object; an adjustment device that includes a holding member having a holding surface smaller than an area size of the object, holds a part of the object from below in a noncontact state using the holding member, and adjusts a position of the object in a direction intersecting the two-dimensional plane; and a drive device that drives the holding member in the one axis direction while adjusting a position of the holding member according to a position of the object with respect to the predetermined area.

With this apparatus, the executing device executes the predetermined processing with respect to a portion subject to processing of a surface of the tabular object, which is driven by the object driving device at a constant speed in one axis direction within the two-dimensional plane, in a predetermined area (processing area) in the movement course of the object. In this case, when the executing device performs the predetermined processing described above, the adjustment device adjusts the position of the object (positions the object) in a direction intersecting the two-dimensional plane, and therefore, the predetermined processing described above can be performed with high precision. Further, since the position of the holding member of the adjustment device is controlled according to the position of the object with respect to the predetermine area (processing area), it becomes possible to perform the positioning of the object in the direction interesting the two-dimensional plane with high precision.

According to a second aspect of the present invention, there is provided a first exposure apparatus that forms a predetermined pattern on an object by irradiating the object with an energy beam and exposing the object, the apparatus comprising: an object driving device that drives a tabular object placed along a predetermined two-dimensional plane that is parallel to a horizontal plane, in at least one axis direction within the two-dimensional plane; an exposure system that irradiates a surface of the object that is driven at a constant speed by the object driving device, with the energy beam in a movement course of the object; an adjustment device that includes a holding member having a holding surface smaller than an area size of the object, holds a part of the object from below in a noncontact state using the holding member, and adjusts a position of the object in a direction intersecting the two-dimensional plane; and a drive device that drives the holding member in the one axis direction according to a position of the object with respect to an irradiation area of the energy beam by the exposure system.

With this apparatus, the exposure system irradiates the surface of the tabular object that is driven at a constant speed in one axis direction within the two-dimensional plane by the object driving device, with an energy beam, in a movement course of the object. In this case, when the exposure system executes the exposure operation, the adjustment device adjusts the position of the object (positions the object) in a direction intersecting the two-dimensional plane, and therefore, exposure processing can be performed with high precision. Further, since the position of the holding member of the adjustment device is controlled according to the position of the object with respect to the irradiation area of the energy beam, it becomes possible to perform the positioning of the object in the direction intersecting the two-dimensional plane with high precision.

According to a third aspect of the present invention, there is provided a second exposure apparatus that forms a predetermined pattern on an object by exposing the object with an energy beam, the apparatus comprising: an optical system that irradiates a partial area within a predetermined two-dimensional plane parallel to a horizontal plane, with the energy beam via the pattern; a drive device that drives a tabular object placed along the two-dimensional plane, in at least one axis direction, within a predetermined area that includes the partial area within the two-dimensional plane; and an adjustment device having a holding surface whose size is nearly the same as or smaller than the partial area, which holds a part of the object opposed to the holding surface, from below in a noncontact state and adjusts a position of the object in a direction intersecting the two-dimensional plane, when the object is driven by the drive device, and which moves in the one axis direction according to a position of the object with respect to the partial area.

With this apparatus, the optical system irradiates the energy beam on a tabular object that is driven by the drive device in one axis direction within the two-dimensional plane and exposes the object. In this case, since the position of the object is set (the object is positioned) in a direction intersecting the two-dimensional plane by the adjustment device when the exposure operation is executed by the optical system, the exposure processing can be performed with high precision. Further, the position of the holding surface of the adjustment device is controlled according to the position of the object with respect to an irradiating area of the energy beam, and therefore, it becomes possible to perform the positioning of the object in the direction intersecting the two-dimensional plane, with high precision.

According to a fourth aspect of the present invention, there is provided a device manufacturing method, comprising: exposing the object using the object processing apparatus or the exposure apparatus of the present invention; and developing the exposed object.

In this case, there is provided a manufacturing method of manufacturing a flat-panel display as a device, by using a substrate for a flat-panel display as an object. The substrate for a flat-panel display includes a film-like member besides a glass substrate.

According to a fifth aspect of the present invention, there is provided an exposure method of forming a predetermined pattern on an object by exposing the object with an energy beam, the method comprising: driving a tabular object placed along a predetermined two-dimensional plane parallel to a horizontal plane, in at least one axis direction, within a predetermined area that includes a partial area within the two-dimensional plane, the partial area being irradiated with the energy beam via the pattern by an optical system; and holding, while changing a position in the one axis direction of a holding surface whose size is nearly the same as or smaller than the partial area, according to a position of the object with respect to the partial area, a section of the object opposed to the holding surface, from below the object in a noncontact state, and adjusting a position of the section in a direction intersecting the two-dimensional plane, when the object is driven.

According to a sixth aspect of the present invention, there is provided a device manufacturing method, comprising: exposing the object using the exposure method of the present invention; and developing the exposed object.

### BRIEF DESCRIPTION OF DRAWINGS

In the accompanying drawings;

FIG. 1 is a view schematically showing a configuration of a liquid crystal exposure apparatus of a first embodiment;

FIG. 2 is a plan view of a substrate stage device which the liquid crystal exposure apparatus of FIG. 1 has;

FIG. 3 is a cross-sectional view taken along the line A-A of FIG. 2;

FIG. 4 is a cross-sectional view of a fixed-point stage which the substrate stage device of FIG. 2 has;

FIG. 5A is a plan view enlargedly showing a part of a substrate holding frame which the substrate stage device of FIG. 2 has, and FIG. 5B is a cross-sectional view taken along the line B-B of FIG. 5A;

FIGS. 6A to 6C are plan views used to explain an operation of the substrate stage device when exposure processing is performed on a substrate;

FIGS. 7A to 7D are plan views (No. 1) used to explain an operation of an air chuck unit during an exposure operation;

FIGS. 8A to 8D are plan views (No. 2) used to explain the operation of the air chuck unit during the exposure operation;

FIGS. 9A and 9B are side views used to explain an operation of the substrate stage device during the exposure operation;

FIG. 10 is a plan view of a substrate stage device related to a second embodiment;

FIG. 11 is a side view of the substrate stage device of FIG. 10;

FIGS. 12A to 12C are plan views used to explain an operation of an air chuck unit during an exposure operation using the substrate stage device of FIG. 10; and

FIG. 13 is a view showing a schematic configuration of a substrate inspecting apparatus related to a third embodiment.

### DESCRIPTION OF EMBODIMENTS

### First Embodiment

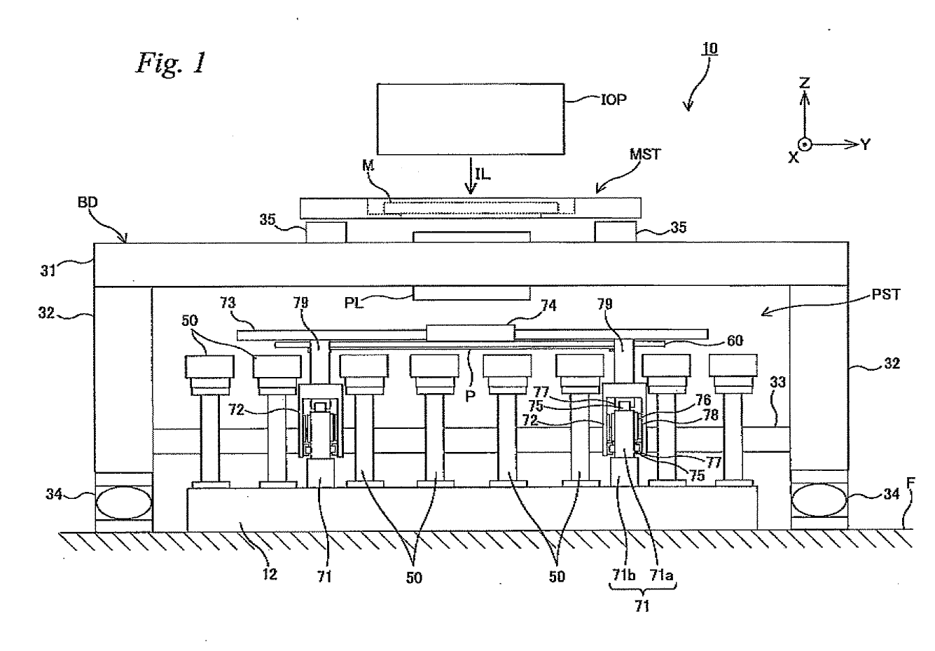

A first embodiment of the present invention is described below, with reference to FIGS. 1 to 9B.

FIG. 1 shows a schematic configuration of a liquid crystal exposure apparatus 10 related to the first embodiment, which is used in the manufacturing of flat-panel displays, e.g. liquid crystal display devices (liquid crystal panels), and the like. Liquid crystal exposure apparatus 10 is a projection exposure apparatus by a step-and-scan method, in which a rectangular glass substrate P (hereinafter, simply referred to as a substrate P) that is used for a display panel of a liquid crystal display device is an exposure subject, which is a so-called scanner.

As shown in FIG. 1, liquid crystal exposure apparatus 10 includes an illumination system IOP, a mask stage MST that holds a mask M, a projection optical system PL, a body BD on which mask stage MST and projection optical system PL described above and the like are mounted, a substrate stage device PST that holds substrate P, and their control system, and the like. In the description below, the explanation is given assuming that a direction in which mask M and substrate P are scanned relative to projection optical system PL, respectively, during exposure is an X-axis direction, a direction orthogonal to the X-axis direction within a horizontal plane is a Y-axis direction, and a direction orthogonal to the X-axis and the Y-axis is a Z-axis direction, and rotational (tilt) directions around the X-axis, Y-axis and Z-axis are θx, θy and θz directions, respectively.

Illumination system IOP is configured similar to the illumination system that is disclosed in, for example, U.S. Pat. No. 6,552,775 and the like. More specifically, illumination system IOP irradiates mask M with light emitted from a light source that is not illustrated (e.g. a mercury lamp), as illumination light for exposure (illumination light) IL, via a reflection mirror, a dichroic mirror, a shutter, a wavelength selecting filter, various types of lenses and the like, which are not illustrated. As illumination light IL, for example, light such as an i-line (with a wavelength of 365 nm), a g-line (with a wavelength of 436 nm) or an h-line (with a wavelength of 405 nm) (or synthetic light of the i-line, the g-line and the h-line described above) is used. Further, the wavelength of illumination light IL can be appropriately switched by the wavelength selecting filter, for example, according to the required resolution.

On mask stage MST, mask M having a pattern surface (the lower surface in FIG. 1) on which a circuit pattern and the like are formed is fixed by, for example, vacuum adsorption (or electrostatic adsorption). Mask stage MST is supported by levitation in a noncontact state, for example, via air bearings that are not illustrated, above a pair of mask stage guides 35 fixed to the upper surface of a barrel surface plate 31 that is a part of body BD to be described later on. Mask stage MST is driven in a scan direction (the X-axis direction) with a predetermined stroke and also is finely driven in the Y-axis direction and the θz direction respectively as needed, above the pair of mask stage guides 35, by a mask stage driving system (not illustrated) that includes, for example, a liner motor. Positional information of mask stage MST within the XY plane (which includes rotational information in the θz direction) is measured by a mask interferometer system including a laser interferometer that is not illustrated.

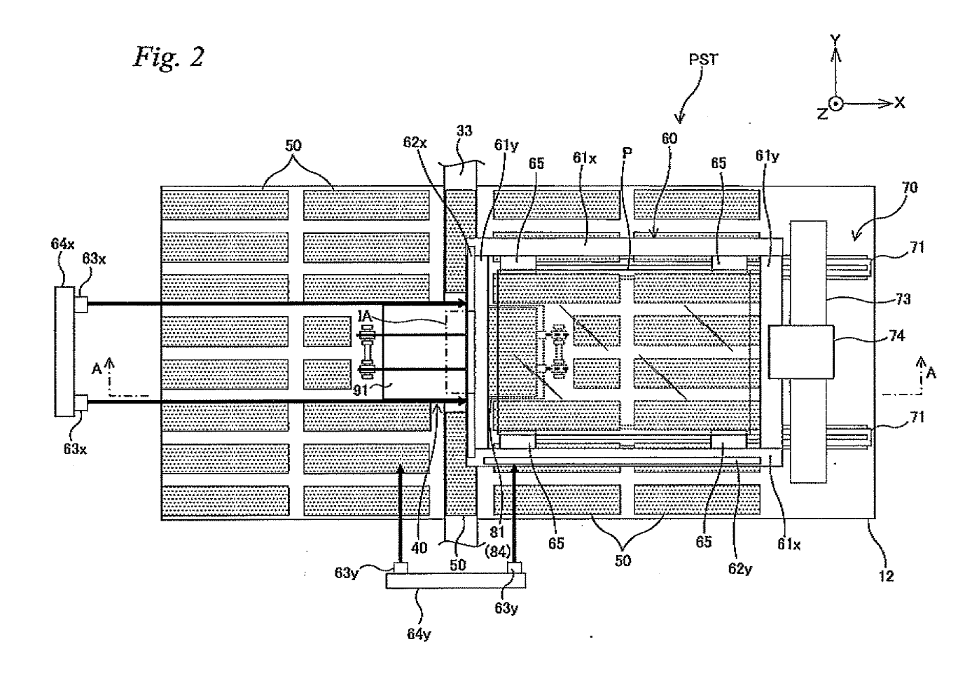

Projection optical system PL is supported below mask stage MST in FIG. 1, by barrel surface plate 31. Projection optical system PL in the present embodiment has a configuration similar to the projection optical system disclosed in, for example, U.S. Pat. No. 6,552,775. More specifically, projection optical system PL includes a plurality of projection optical systems whose projection areas of a pattern image of mask M are placed in a zigzag shape (a multi-lens projection optical system), and functions equivalently to a projection optical system having a single rectangular image field with the Y-axis direction serving as its longitudinal direction. In the present embodiment, as each of the plurality of projection optical systems, for example, a both-side telecentric equal-magnification system that forms an erected normal image is used. Further, in the description below, the plurality of projection areas placed in the zigzag shape of projection optical system PL are collectively referred to as an exposure area IA (see FIG. 2).

Therefore, when the illumination area on mask M is illuminated with illumination light IL from illumination system IOP, by illumination lights IL that has passed through mask M, a projected image (partial erected image) of a circuit pattern of mask M within the illumination area is formed, via projection optical system PL, on the irradiation area (exposure area IA) of illumination light IL, which is conjugate to the illumination area, on substrate P which is placed on the image plane side of projection optical system PL and whose surface is coated with a resist (sensitive agent). Then, by moving mask M relative to the illumination area (illumination light IL) in the scan direction (X-axis direction) and also moving substrate P relative to exposure area IA (illumination light IL) in the scan direction (X-axis direction) by synchronous drive of mask stage MST and substrate stage device PST, scanning exposure of one shot area (divided area) on substrate P is performed, and a pattern of mask M (mask pattern) is transferred onto the shot area. More specifically, in the present embodiment, a pattern of mask M is generated on substrate P by illumination system TOP and projection optical system PL, and the pattern is formed on substrate P by exposure of a sensitive layer (resist layer) on substrate P with illumination lights IL.

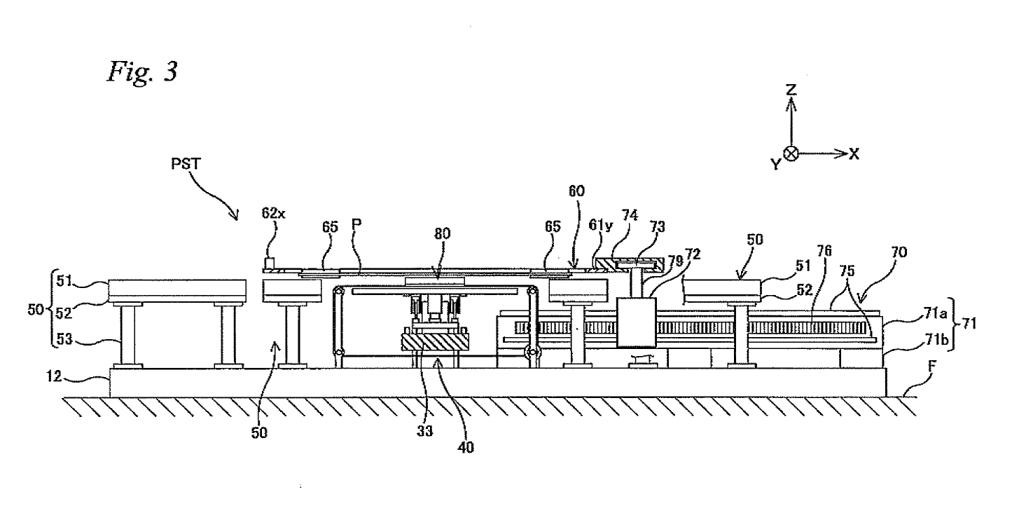

As disclosed in, for example, U.S. Patent Application Publication No 2008/0030702 and the like, body BD has barrel surface plate 31 described earlier, and a pair of support walls 32 that support the +Y side end and the −Y side end of barrel surface plate 31 from below, on a floor surface F. Each of the pair of support walls 32 is supported on floor surface F via a vibration isolation table 34 that includes, for example, an air spring, and body BD is separated from floor surface F in terms of vibration. Further, between the pair of support walls 32, a Y beam 33 made up of a member having a rectangular sectional shape (see FIG. 3) arranged extending parallel to the Y-axis is installed. Between the lower surface of Y beam 33 and the upper surface of a surface plate 12 to be described later on, a predetermined clearance (interspace/interval/gap/spatial distance) is formed. More specifically, Y beam 33 and surface plate 12 are noncontact and are separated in terms of vibration.

Substrate stage device PST is equipped with surface plate 12 installed on floor surface F, a fixed-point stage 40 (see FIG. 2) that holds substrate P from below in a noncontact manner and adjusts the position (hereinafter, referred to as the surface position) of substrate P in at least one direction of the Z-axis direction, the θx direction and the θy direction, a plurality of air levitation units 50 installed on surface plate 12, a substrate holding frame 60 that holds substrate P and a drive unit 70 that drives substrate holding frame 60 in the X-axis direction and the Y-axis direction (along the XY plane).

As shown in FIG. 2, surface plate 12 is made up of a member having a rectangular plate shape whose longitudinal direction is in the X-axis direction in a planar view (when viewed from the +Z side).

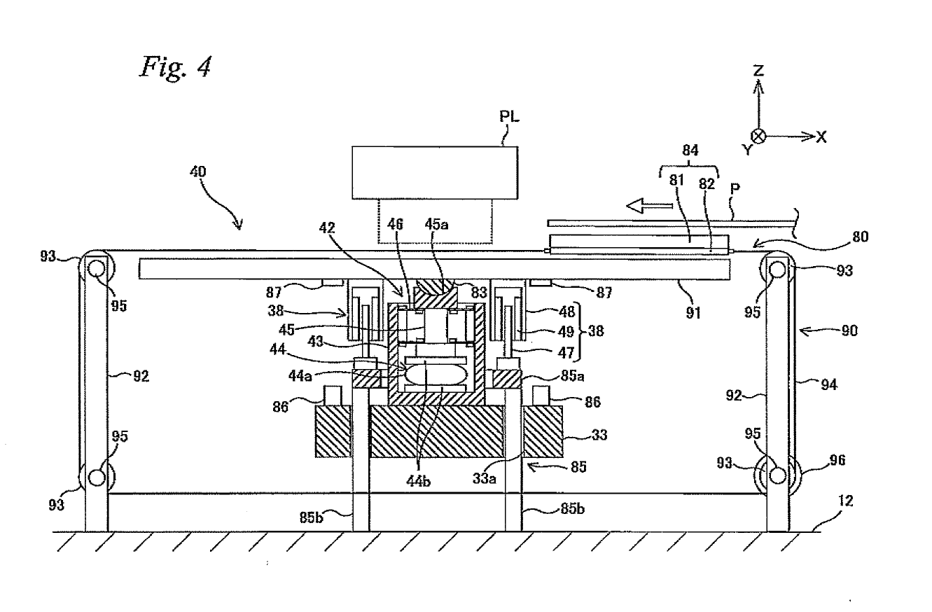

As shown in FIG. 2, fixed-point stage 40 is placed at a position that is slightly on the −X side from the center on surface plate 12. Further, as shown in FIG. 4, fixed-point stage 40 is equipped with a weight canceller 42 mounted on Y beam 33, a chuck member 84 (a part of an air chuck unit 80 to be described later on) supported by weight canceller 42, an actuator used to drive the chuck member in a direction intersecting the XY plane, for example, a plurality of Z voice coil motors 38 (hereinafter, shortly referred to as Z-VCMs 38), and the like. Incidentally, the illustration of the plurality of air levitation units 50, substrate holding frame 60, drive unit 70 and the like is omitted in FIG. 4, in order to prevent intricacy of the drawing.

Weight canceller 42 is equipped with a case 43, for example, fixed to Y beam 33, an air spring 44 housed in the lowermost section inside case 43, and a Z slider 45 supported by air spring 44. Case 43 is made up of a cylinder-like member having a bottom which is opened on the +Z side. Air spring 44 has a bellows 44a made up of a hollow member formed with a rubber-based material, and a pair of plates 44b (e.g. metal plates) parallel to the XY plane that are placed on (on the +Z side of) and under (on the −Z side of) bellows 44a. The inside of bellows 44a is set to be a positive pressure space whose pressure is higher compared with the outside, because a gas is supplied from a gas supplying device that is not illustrated. Weight canceller 42 reduces the load on the plurality of Z-VCMs 38 by cancelling out the weight (a downward (the −Z direction) force owing to the gravitational acceleration) of substrate P, chuck member 84, Z slider 45 and the like, with an upward (the +Z direction) force generated by air spring 44.

Z slider 45 is made up of a columnar member arranged extending parallel to the Z-axis whose lower end is fixed to plate 44b placed on the +Z side of air spring 44. Z slider 45 is connected to the inner wall surface of case 43 via a plurality of parallel plate springs 46. Parallel plate spring 46 has a pair of plate springs parallel to the XY plane that are placed apart in the vertical direction. Parallel plate springs 46 connect Z slider 45 and case 43 at, for example, four positions in total which are on the +X side, the −X side, the +Y side and the −Y side of the Z slider (the parallel plate springs on the +Y side and the −Y side of Z slider 45 are not illustrated). While relative movement of Z slider 45 with respect to case 43 in directions parallel to the XY plane is restricted owing to the stiffness (extensional stiffness) of the respective parallel plate springs 46, Z slider 45 can be relatively moved with a minute stroke with respect to case 43 in the Z-axis direction owing to the flexibility of the respective parallel plate springs 46. Consequently, Z slider 45 vertically moves with respect to Y beam 33 by the pressure of the gas within bellows 44a being adjusted. Incidentally, a member that generates an upward force used to cancel the weight of substrate P is not limited to the air spring (bellows) described above, but can be an air cylinder, a coil spring, or the like. Further, as a member that restricts the position of the Z slider within the XY plane, for example, a noncontact thrust bearing (e.g. a static gas bearing such as an air bearing) whose bearing surface is opposed to the side surface of the Z slider, or the like can also be used (refer to PCT International Publication No. 2008/129762 (the corresponding U.S. Patent Application Publication No. 2010/0018950)).

As shown in FIG. 4, air chuck unit 80 is equipped with chuck member 84 that holds by adsorption a part of substrate P in a noncontact manner from the lower surface side, a drive unit 90 that drives chuck member 84 in the X-axis direction, and a guide plate 91 that guides movement of chuck member 84. Chuck member 84 includes a chuck main body 81 and a base 82 integrally fixed to the lower surface of chuck main body 81. Chuck main body 81 is made up of a rectangular parallelepiped member that is low in a height direction (of a thin type), and its upper surface (the surface on the +Z side) is rectangular whose longitudinal direction is in the Y-axis direction in a planar view (see FIG. 2). The area size of the upper surface of chuck main body 81 is set larger than exposure area IA, and especially the size in the X-axis direction that is the scan direction is set longer than the size of exposure area IA in the X-axis direction.

Chuck main body 81 has a plurality of gas jetting ports, which are not illustrated, on its upper surface, and supports substrate P by levitation by jetting a gas supplied from a gas supplying device that is not illustrated, for example, high-pressure air toward the lower surface of substrate P. Furthermore, chuck main body 81 has a plurality of gas suctioning ports, which are not illustrated, on the upper surface. A gas suctioning device (vacuum device) that is not illustrated is connected to chuck main body 81, and the gas suctioning device suctions a gas between the upper surface of chuck main body 81 and the lower surface of substrate P via the gas suctioning ports of chuck main body 81, and generates the negative pressure between chuck main body 81 and substrate P. Chuck member 84 holds substrate P by adsorption in a noncontact manner using a balance between the pressure of the gas jetted from chuck main body 81 to the lower surface of substrate P and the negative pressure generated when the gas between chuck main body 81 and the lower surface of substrate P is suctioned. In this manner, since chuck member 84 places so-called preload on substrate P, the stiffness of the gas (air) membrane formed between chuck main body 81 and substrate P can be increased, and accordingly, even if substrate P has deformation or warpage, a part of substrate P can surely be redressed along the upper surface (substrate holding surface) of chuck main body 81. However, chuck main body 81 does not restrict the position of substrate P within the XY plane, and therefore, substrate P can move relative to illumination light IL (see FIG. 1) in the X-axis direction (scan direction) and the Y-axis direction (step direction) even if substrate P is in a state held by adsorption by chuck main body 81.

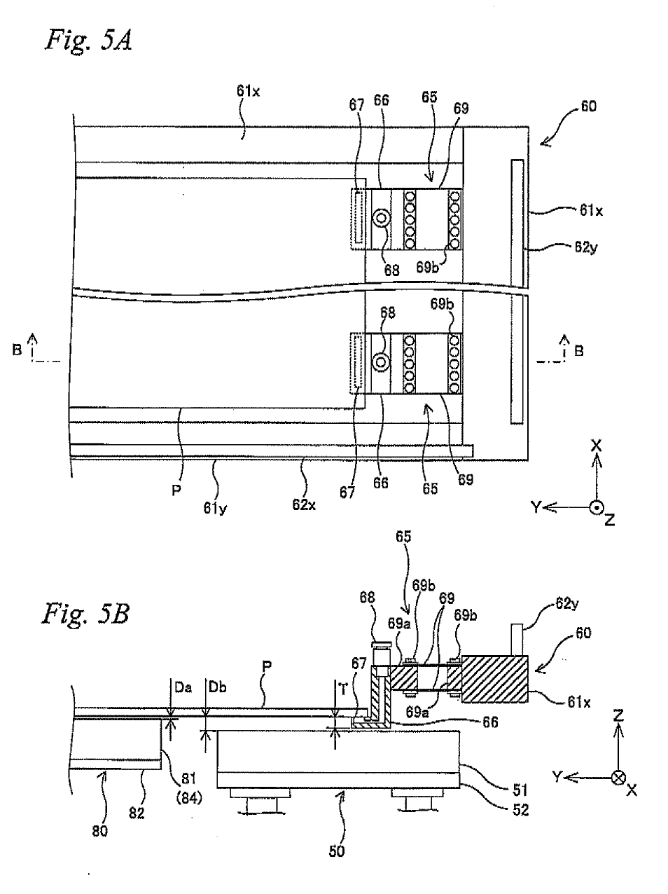

Now, as shown in FIG. 5B, in this embodiment, the flow rate and the pressure of the gas jetted from the upper surface of chuck main body 81 and the flow rate and the pressure of the gas suctioned by the gas suctioning device are set such that a distance Da (clearance (interspace/interval/gap/spatial distance)) between the upper surface (substrate holding surface) of chuck main body 81 and the lower surface of substrate P is, for example, around 0.02 mm. Incidentally, the gas jetting ports and the gas suctioning ports can be formed by the mechanical processing, or the chuck main body 81 is formed with a porous material and its holes can be used as the gas jetting ports and the gas suctioning ports. The details of the configuration and the functions of this type of the air chuck member (vacuum preload air bearing) are disclosed in, for example, PCT International Publication No. 2008/121561 and the like.

Referring back to FIG. 4, base 82 is made up of a plate-shaped member. Base 82 has a static gas bearing that is not illustrated, for example, an air bearing on its lower surface, and jets a gas, for example, air to the upper surface of a guide plate 91 to be described later. Owing to the stiffness of a gas membrane formed between base 82 and guide plate 91, a constant clearance (interspace/interval/gap/spatial distance) is formed between the lower surface of base 82 and the upper surface of guide plate 91.

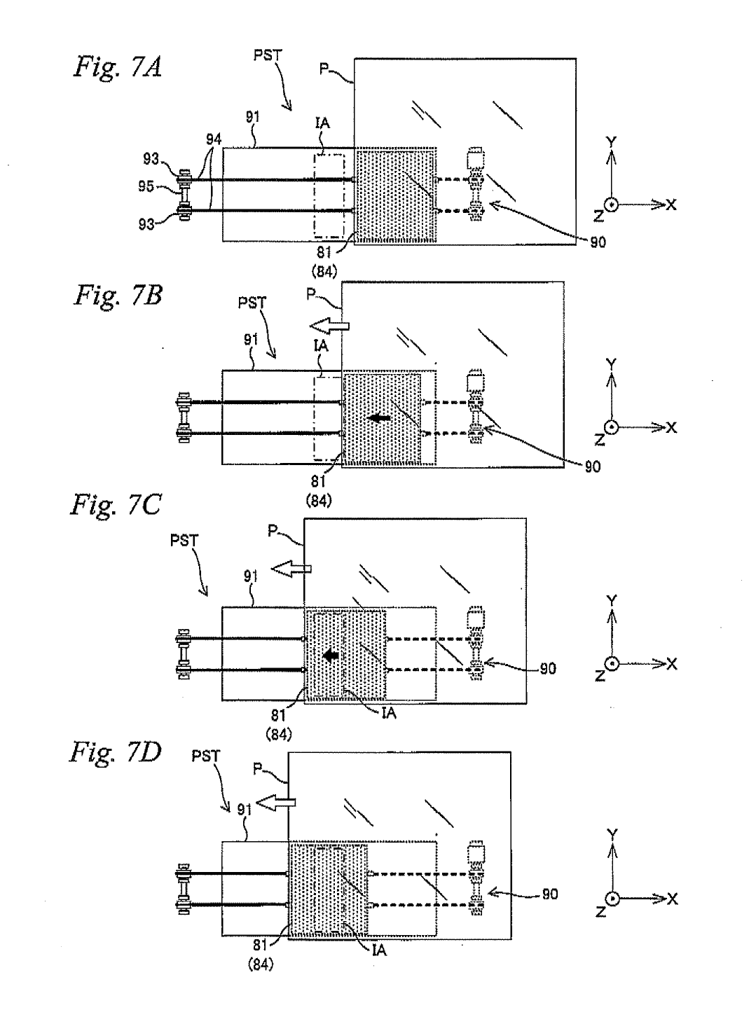

A drive unit 90 that drives chuck member 84 in the X-axis direction has support posts 92 each one of which is placed on the +X side and the −X side of Y beam 33, each one pair of pulleys 93 (see FIG. 7A) that are respectively arranged in the vicinity of the upper end and the lower end of the respective support posts 92 (at four positions in total), and two drive belts 94 (see FIG. 7A). Each of the pair of support posts 92 is made up of a columnar member arranged extending parallel to the Z-axis and has the −Z side end that is connected to surface plate 12. Pulleys 93 being paired are placed at a predetermined distance in the Y-axis direction (see FIG. 7A). Each of pulleys 93 being paired is supported so as to be rotatable around a shaft 95 that is parallel to the Y-axis. To shaft 95 that supports the pair of pulleys 93 on the +X side located on the −Z side, a drive device, for example, an electric motor 96, used to rotate the shaft 95 is connected. Electric motor 96 is controlled by a main controller that is not illustrated.

The two drive belts 94 are placed parallel to each other at a predetermined distance in the Y-axis direction (see FIG. 7A). One end of each of the two drive belts 94 is connected to the side surface on the +X side of base 82. Further, the mid portion of each of the two drive belts 94 is wrapped around pulley 93 on the +X side located on the +Z side, pulley 93 on the +X side located on the −Z side, pulley 93 on the −X side located on the −Z side, and pulley 93 on the −X side located on the +Z side, in the order starting from the side of the one end, while the other end of each of the two drive belts 94 is fixed to the side surface on the −X side of base 82. Of the pair of drive belts 94, a portion stretched between the pair of pulleys 93 on the +X side located on the −Z side and the pair of pulleys 93 on the −X side located on the −Z side passes below Y beam 33.

Consequently, when pulley 93 on the +X side located on the side is rotated by the electric motor, chuck member 84 is towed by drive belt 94 owing to a frictional force generated between the pulley 93 and drive belt 94, and integrally moves in the +X direction or the −X direction. Open-loop control of the position of chuck member 84 is performed by the main controller that is not illustrated, based on the number of rotations of the pulley 93 for shaft 95) that is measured using, for example, a rotary encoder or the like. Incidentally, the configuration of the drive device used to drive chuck member 84 in the X-axis direction is not limited thereto, but the chuck member can be driven by a drive device that includes a feed screw mechanism or a rack-and-pinion mechanism, or a liner motor. Further, the chuck member can be towed using, for example, a rope or the like, in place of the drive belt described above.

In the center of the lower surface of guide plate 91, a static gas bearing having a semispherical shaped bearing surface, e.g., a spherical air bearing 83 is fixed. Spherical air bearing 83 is fitted into a concave section 45a formed on the end surface on the +Z side (upper surface) of Z slider 45. Accordingly, guide plate 91 is supported, by Z slider 45, swingably with respect XY plane (rotatably in the θx and θy directions). As described earlier, a constant clearance (interspace/interval/gap/spatial distance) is formed between guide plate 91 and chuck member 84 (base 82), and therefore, when guide plate 91 swings with respect to the XY plane, chuck member 84 slides integrally with guide plate 91 with respect to XY plane. Incidentally, as a structure that supports guide plate 91 swingably with respect to the XY plane, a quasi-spherical bearing structure that uses a plurality of air pads (air bearings) that is disclosed in, for example, PCT International Publication No. 2008/129762 can also be employed, or an elastic hinge device can also be used.

One each of a plurality, four in this embodiment, of Z-VCMs 38 is arranged on the +X side, the −X side, the +Y side and the −Y side of weight canceller 42 (as for Z-VCM 38 on the −Y side, see FIG. 3, and the illustration of the Z-VCM on the +Y side is omitted). The four Z-VCMs 38 have the same configuration and functions except that their setting positions are different. Each of the four Z-VCMs 38 includes a Z stator 47 fixed to a base frame 85 installed on surface plate 12 and a Z mover 48 fixed to the lower surface of guide plate 91.

Base frame 85 includes a main section 85a made up of a plate-shaped member formed so as to have an annular shape in a planar view and a plurality of leg sections 85b that support main section 85a from below on surface plate 12. Main section 85a is placed above Y beam 33 and weight canceller 42 is inserted in an opening section formed in the center portion of main section 85a. Therefore, main section 85a is noncontact with each of Y beam 33 and weight canceller 42. Each of the plurality (three or more, in this case) of leg sections 85b is made up of a member arranged extending parallel to the Z-axis, and the +Z side end of leg section 85b is connected to main section 85a and the −Z side end is fixed to surface plate 12. The plurality of leg section 85b are respectively inserted in a plurality of through-holes 33a, which are formed in Y beam 33 so as to respectively correspond to the plurality of leg sections 85b and which penetrate in the Z-axis direction, and the plurality of leg section 85b are noncontact with Y beam 33.

Z mover 48 is made up of a member having an inverse U-like sectional shape and has a magnetic unit 49 including magnets on each of a pair of opposed surfaces. Meanwhile, Z stator 47 has a coil unit including coils (the illustration is omitted) and the coil unit is inserted between a pair of magnetic units 49. The magnitude, the direction and the like of the electric current supplied to the coils of Z stator 47 are controlled by the main controller that is not illustrated, and when the electric current is supplied to the coils of the coil unit, Z mover 48 (i.e. guide plate 91) is driven with respect to Z stator 47 (i.e. base frame 85) in the Z-axis direction by the electromagnetic force (Lorentz force) generated by the electromagnetic interaction between the coil unit and the magnetic unit. The main controller, which is not illustrated, drives (vertically moves) guide plate 91 in the Z-axis direction by synchronously controlling the four Z-VCMs 38. Further, the main controller swings guide plate 91 in arbitrary directions with respect to the XY plane (drives guide plate 91 in the θx direction and the θy direction) by appropriately controlling the magnitude, the direction and the like of the electric current supplied to each of the coils that the four Z stators 47 have. With this operation, fixed-point stage 40 adjusts at least one of the position in the Z-axis direction and the positions in the θx and the θy directions of the portion, held by chuck member 84 (chuck main body 81), of substrate P. Incidentally, while each of the Z-axis VCM in the present embodiment is a voice coil motor by a moving magnet type in which the mover has the magnetic unit, this is not intended to be limiting, and each of the VCMs can be a voice coil motor by a moving coil type in which the mover has the coil unit. Further, the drive method can be drive methods other than the Lorentz force drive method.

In this case, since Z stator 47 of each of the four Z-VCMs 38 is mounted on base frame 85, the reaction force of the drive force, which acts on Z stator 47 when guide plate 91 is driven in the Z-axis direction or the θx and the θy directions using the four Z-VCMs 38, is not transmitted to Y beam 33. Consequently, when guide plate 91 is driven using Z-VCMs 38, the operation of weight canceller 42 is not affected at all. Further, because the reaction force of the drive force is not transmitted to body BD that has Y beam 33 as well, the reaction force of the drive force does not affect projection optical system PL and the like when guide plate 91 is driven using Z-VCMs 38. Incidentally, the number of Z-VCMs 38 can be three if the three Z-VCMs are arranged, for example, at three noncollinear positions, because the Z-VCMs only should vertically move guide plate 91 along the Z-axis direction and swing guide plate 91 in arbitrary directions with respect to the XY plane.

Positional information of guide plate 91 that is driven by Z-VCMs 38 is obtained using a plurality, e.g. four in the embodiment, of Z sensors 86. One each of Z sensors 86 is arranged on the +X side, the −X side, the +Y side and the −Y side of weight canceller 42 so as to correspond to the four Z-VCMs 38 (the illustration of the Z sensors on the +Y side and on the −Y side is omitted). Accordingly, in the present embodiment, the drive point (the point of action of the drive force) by the Z-VCMs on a driven object (in this case, guide plate 91) that is driven by the Z-VCMs and the measurement points by Z sensors 86 are made to be closely arranged, and thereby the stiffness of the driven object between the measurement points and the drive point is increased, which increases the controllability of Z sensors 86. More specifically, Z sensors 86 output the accurate measurement values that correspond to the drive distance by the driven object, thereby aiming at decreasing the positioning time. It is desirable for Z sensors 86 to have a short sampling period, from the viewpoint of increasing the controllability.

The four Z sensors 86 are substantially the same sensors. Z sensor 86 configures, together with a target 87 fixed to the lower surface of guide plate 91, a position sensor by, for example, a capacitance method (or an eddy current method) that obtains the positional information of guide plate 91 in the Z-axis direction with Y beam 33 serving as a reference. Since the distance between the upper surface of guide plate 91 and the lower surface of base 82 is constant as described earlier, the main controller, which is not illustrated, can constantly obtain positional information of chuck member 84 in the Z-axis direction and each of the θx and θy directions based on the outputs of the four Z sensors 86, and controls the position of the upper surface of chuck member 84 by appropriately controlling the four Z-VCMs 38 based on the measurement values. In this case, the final position of chuck member 84 is controlled such that the upper surface of substrate P that passes close to above air chuck unit 80 is constantly at the focal position height of projection optical system PL. While monitoring the position of the upper surface (the surface position) of substrate P with a surface position measuring system (autofocus device) that is not illustrated, the main controller, which is not illustrated, drives and controls chuck member 84 using the positional information from Z sensors 86 that have high controllability such that the upper surface of substrate P is constantly located within a depth of focus of projection optical system PL (such that projection optical system PL is focused on the upper surface of substrate P at all times). In this case, the surface position measuring system (autofocus device) has a plurality of measurement points whose positions in the Y-axis direction are different within exposure area IA. For example, at least one measurement point is placed in each projection area. In this case, the plurality of measurement points are placed in two rows spaced apart in the X-axis direction, in accordance with the zigzag-shaped placement of the plurality of projection areas. Consequently, based on the measurement values of the plurality of measurement points (the surface positions), the pitching amount (θy rotation) and the rolling amount (θx rotation) of substrate P can be obtained, in addition to the Z-position of the substrate P surface of exposure area IA portion. Further, the surface position measuring system can have a measurement point on the outer side of exposure area IA in the Y-axis direction (non-scan direction), separately from or in addition to the plurality of measurement points. In this case, by using the measurement values of the two measurement points located outermost in the Y-axis direction that include the measurement point located on the outer side, it becomes possible to more accurately obtain the rolling amount (θx rotation). Further, the surface position measuring system can have another measurement point at a position slightly away in the X-axis direction (scan direction) on the outer side of exposure area IA. In this case, so-called read-ahead control of focus/leveling of substrate P becomes possible. Besides, instead of or in addition to the plurality of measurement points at least one of which is placed in each projection area, the surface position measuring system can have a plurality of measurement points disposed in the Y-axis direction at positions away from exposure area IA in the X-axis direction (scan direction) (the placement area of such plurality of measurement points corresponds to the position of exposure area IA in the Y-axis direction). In such a case, it becomes possible to perform the focus mapping that acquires the distribution of surface positions of substrate P in advance, prior to exposure start, for example, during alignment measurement. During the exposure, the focus/leveling control of substrate P is performed using information obtained in the focus mapping. The focus mapping of a substrate and focus/leveling control of the substrate during exposure using the information of the focus mapping are disclosed in detail in, for example, U.S. Patent Application Publication No. 2008/0088843 and the like.

Incidentally, the number of the Z sensors can be three if the three Z sensors are arranged, for example, at three noncollinear positions, because the Z sensors only should obtain positional information of guide plate 91 in the Z-axis direction and each of the θx and θy directions.

The plurality of air levitation units 50 (e.g. 34 units in this embodiment) prevent the vibration from the outside from being transmitted to substrate P, preventing substrate P from deforming (bending) and breaking because of the self weight, restraining occurrence of size error in each of the X and Y directions (or positional deviation within the XI plane) of substrate P that is caused by bending of substrate P in the Z-axis direction because of the self weight, and so on, by supporting substrate P (in this case, excluding the portion held by fixed-point stage 40 described previously) from below in a noncontact manner such that substrate P is maintained roughly parallel to a horizontal plane.

The plurality of air levitation units 50 have substantially the same functions except for their placement positions or sizes are different. In the present embodiment, as shown in FIG. 2, for example, one each of air levitation unit 50 is placed on the +Y side and the −Y side of fixed-point stage 40, and two rows of air levitation unit rows, each of which is composed of, for example, eight air levitation units 50 disposed at an equal distance along the I-axis direction, are placed at a predetermined distance along the X-axis direction on each of the +X side and the −X side of fixed-point stage 40. More specifically, the plurality of air levitation units 50 are placed so as to enclose the periphery of fixed-point stage 40. In the description below, the explanation is given assuming that the four rows of the air levitation unit rows are referred to as the first to fourth rows starting from the −X side for the sake for convenience, and the eight air levitation units that configure each air levitation unit row are referred to as the first to eighth units starting from the −Y side for the sake for convenience. Incidentally, although the fourth and fifth air levitation units 50 that configure the second and third air levitation unit rows are smaller compared with the other air levitation units 50, the capability (e.g. the air jetting amount per unit area) of the fourth and fifth air levitation units 50 is the same as that of the other air levitation units 50.

As shown in FIG. 3, each of air levitation units 50 includes, for example, a main section 51 that jets a gas (e.g. air) to the lower surface of substrate P, a support section 52 that supports main section 51 from below, and a plurality of, e.g. a pair of, leg sections 53 that support support section 52 from below on surface plate 12. Main section 51 is made up of a member having a rectangular parallelepiped shape and has a plurality of gas jetting ports on its upper surface (the surface on the +Z side). Main section 51 supports substrate P by levitation by jetting the gas (air) toward the lower surface of substrate P, and guides movement of substrate P when substrate P moves along the XY plane. The upper surface of each of the plurality of air levitation units 50 is located on the same XY plane. Incidentally, the air levitation unit can be configured such that the gas is supplied from a gas supplying device, which is not illustrated, arranged outside, or the air levitation unit itself can have a blower, e.g. a fan or the like. In this embodiment, as shown in FIG. 5B, the pressure and the flow rate of the gas jetted from main section 51 are set such that a distance Db (clearance (interspace/interval/gap/spatial distance)) between the upper surface (air jetting surface) of main section 51 and the lower surface of substrate P is, for example, around 0.8 mm. Incidentally, the gas jetting ports can be formed by the mechanical processing or the main section is formed with a porous material and its holes can be used as the gas jetting ports.

Support section 52 is made up of a plate-shaped member having a rectangular shape in a planar view, and its lower surface is supported by the pair of leg sections 53. Incidentally, the leg sections of a pair (two) of air levitation units 50 placed on the side and the −Y side of fixed-point stage 40, respectively, are configured so as not to come in contact with Y beam 33 (e.g. the leg sections are each formed into an inverse U-like shape and placed astride Y beam 33). Incidentally, the number and the placement of a plurality of the air levitation units are not limited to those described above as an examples, and for example, the number and the placement can appropriately be changed in accordance with, for example, the size, shape, weight and movable range of substrate P or the capability of each air levitation unit, or the like. Further, the shape of the support surface (gas jetting surface) of each of the air levitation units, the distance between the adjacent air levitation units and the like are also not limited in particular. The point is that the air levitation units should be placed so as to cover the entire area of a movable range where substrate P can move (or an area slightly larger than the movable range).

As shown in FIG. 2, substrate holding frame 60 is formed into a frame shape having a rectangular outer shape (contour) with the X-axis direction serving as its longitudinal direction in a planar view. Substrate holding frame 60 has a pair of X frame members 61x, each of which is a tabular member parallel to the XY plane with the X-axis direction serving as its longitudinal direction, at a predetermined distance in the Y-axis direction, and the +X side ends of the pair of X frame members 61x are connected and the −X side ends of the pair of X frame members 61x are connected, respectively, by a Y frame member 61y that is a tabular member parallel to the XY plane with the Y-axis direction serving as its longitudinal direction. It is preferable from the viewpoint of securement of stiffness and reduction in weight that each of the pair of X frame members 61x and a pair of Y frame members 61y is formed with a fiber reinforcing synthetic resin material such as GFRP (Glass Fiber Reinforced Plastics) or ceramics.

On the upper surface of X frame member 61x on the −Y side, a Y movable mirror 62y having a reflection surface orthogonal to the Y-axis on its Y-side surface is fixed. And, on the upper surface of Y frame member 61y on the −X side, an X movable mirror 62x having a reflection surface orthogonal to the X-axis on its −X side surface is fixed. Positional information within the XY plane (including rotational information in the θz direction) of substrate holding frame 60 (i.e. substrate P) is constantly detected at a resolution of, for example, around 0.25 nm with a laser interferometer system that includes a plurality, e.g. two, of X laser interferometers 63x that irradiate the reflection surface of X movable mirror 52x with measurement beams and a plurality, e.g. two, of Y laser interferometers 63y that irradiate the reflection surface of movable mirror 62y with measurement beams. X laser interferometers 63x and Y laser interferometers 63y are fixed to body BD (not illustrated in FIG. 3, see FIG. 1) via predetermined fixing members 64x and 64y, respectively. Incidentally, the number of X laser interferometers 63x and the distance therebetween, and the number of Y laser interferometers 63y and the distance therebetween are set such that the measurement beam from at least one interferometer of the respective interferometers is irradiated on the corresponding movable mirror within the movable range where substrate holding frame 60 is movable. Consequently, the number of the respective interferometers is not limited to two, but for example, can be one or three or more, depending on the movement stroke of the substrate holding frame. Further, in the case of using a plurality of measurement beams, it is also possible that a plurality of optical systems are provided and the light source and the control unit are shared by the plurality of measurement beams.

Substrate holding frame 60 has a plurality, e.g. four, of holding units 65 that hold the end (the outer peripheral portion) of substrate P by vacuum adsorption from below. Two each of the four holding units 65 are attached to the opposed surfaces of the pair of X frame members 61x that are opposed to each other, so as to be spaced apart in the X-axis direction. Incidentally, the number and the placement of the holding units are not limited to those described above, but the extra holding units) can be added as needed, for example, in accordance with the size and the vulnerability to bending of a substrate, and the like. Further, the holding units can be attached to the Y frame members.

As can be seen from FIGS. 5A and 53, holding unit 65 has a hand 66 that is formed so as to have an L-like YZ sectional shape. On a substrate mounting surface section of hand 66, an adsorption pad 67 used to hold substrate P by adsorption, for example, by vacuum adsorption is arranged. Further, on the upper end of hand 66, a joint member 68 is arranged, to which one end of a tube (the illustration is omitted) is connected while the other end of the tube is connected to a vacuum device that is not illustrated. Adsorption pad 67 and joint member 68 communicate with each other via a piping member arranged inside hand 66. On each of the surface of hand 66 and the surface of X frame member 61x that are opposed to each other, a protrusion section 69a that protrudes is formed, and between a pair of protrusion sections 69a that are opposed to each other, a pair of plate springs 69 that are parallel to the XI plane and spaced apart in the Z-axis direction are installed via a plurality of bolts 69b. More specifically, hand 66 and X frame member 61x are connected by the parallel plate springs. Consequently, the position of hand 66 is restricted in the X-axis direction and the Y-axis direction with respect to X frame member 61x owing to the stiffness of plate springs 69, and on the other hand, regarding the Z-axis direction (vertical direction), hand 66 can be displaced in the Z-axis direction (can vertically move) without rotating in the θx direction owing to the elasticity of plate springs 69.

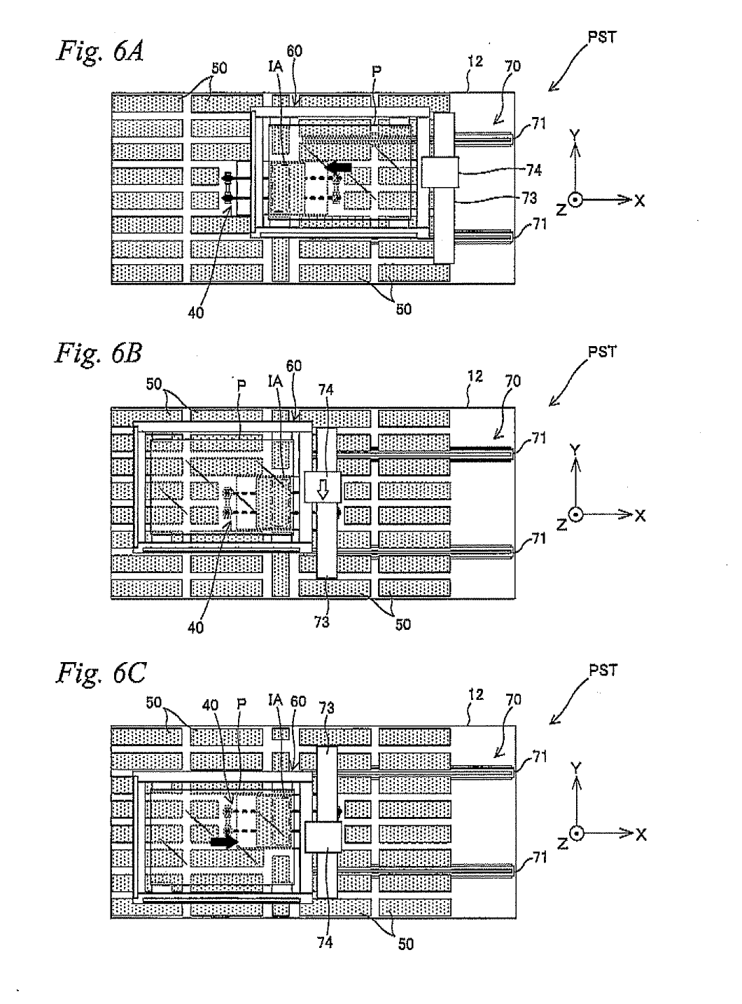

In this case, the lower end surface (−Z side end surface) of hand 66 protrudes on the −Z side, below the lower end surface (−Z side end surface) of each of the pair of X frame members 61x and the pair of Y frame members 61y. However, a thickness T of the substrate mounting surface section of hand 66 is set less (e.g. set to around 0.5 mm) than distance Db (e.g. around 0.8 mm in the present embodiment) between the gas jetting surfaces of air levitation units 50 and the lower surface of substrate P. Therefore, a clearance (interspace/interval/gap/spatial distance) of, for example, around 0.3 mm is formed between the lower surface of the substrate mounting surface section of hand 66 and the upper surfaces of the plurality of air levitation units 50, and when substrate holding frame 60 moves parallel to the XY plane above the plurality of air levitation units 50, hand 66 and air levitation units 50 do not come in contact. Incidentally, as shown in FIGS. 6A to 6C, during an exposure operation of substrate P, hand 66 does not passes above fixed-point stage 40, and therefore, hand 66 and chuck member 84 do not come in contact as well. Incidentally, the substrate mounting surface section of hand 66 has a low stiffness in the Z-axis direction because the substrate mounting surface section is thin as described above, but the area size of a portion that comes in contact with substrate P (flat portion parallel to the XY plane) can be increased, and accordingly the adsorption pad can be increased in size, which improves the adsorption force of the substrate. Further, the stiffness of the hand itself in directions parallel to the XY plane can be secured.

As shown in FIG. 3, drive unit 70 has a pair of X guides 71 fixed on surface plate 12, a pair of X movable sections 72 (the illustration of the X movable section on the −Y side is omitted) that are respectively mounted on the pair of X guides 71 and are movable in the X-axis direction on X guides 71, a Y guide 73 installed over the pair of X movable sections 72, and a Y movable section 74 that is mounted on Y guide 73 and is movable in the Y-axis direction on Y guide 73. Y frame member 61y on the +X side of substrate holding frame 60 is fixed to Y movable section 74, as shown in FIGS. 2 and 3.

The pair of X guides 71 are substantially the same guides except that their placement positions are different. The pair of X guides 71 are placed at a predetermined distance in the Y-axis direction in an area on the +X side from Y beam 33, as shown in FIG. 2. One X guide 71 (on the −Y side) is placed between the second air levitation units 50 and the third air levitation units 50 that configure the third and the fourth air levitation unit rows, and the other X guide 71 (on the +Y side) is placed between the sixth air levitation units 50 and the seventh air levitation units 50 that configure the third and the fourth air levitation unit rows. Further, each of X guides 71 extends on the +X side beyond the fourth air levitation unit row. Incidentally, in FIG. 3, from the viewpoint of preventing intricacy of the drawing, the illustration of air levitation units 50 is partially omitted. Each of the pair of X guides 71 has a main section 71a made up of a plate-shaped member parallel to the XZ plane with the X-axis direction serving as its longitudinal direction and a plurality, e.g. three, of support tables 71b that support main section 71a on surface plate 12 (see FIG. 1). The position in the Z-axis direction of main section 71a is set such that the upper surface of main section 71a is located lower than the respective support sections 52 of the plurality of air levitation units 50.

On each of the side surface on the +Y side, the side surface on the −Y side and the upper surface (the surface on the +Z side) of main section 71a, as shown in FIG. 1, an X linear guide 75 arranged extending parallel to the X-axis direction is fixed. Further, on each of the side surface on the +Y side and the side surface on the −Y side of main section 71a, a magnetic unit 76 including a plurality of magnets disposed along the X-axis direction is fixed (see FIG. 3).

As shown in FIG. 1, each of the pair of X movable sections 72 is made up of a member having an inverse U-like YZ sectional shape, and X guide 71 described earlier is inserted between a pair of opposed surfaces of the member. On each of the inner side surfaces (the ceiling surface and the pair of opposed surfaces that are opposed to each other) of each of the pair of X movable sections 72, a slider 77 formed so as to have a U-like sectional shape is fixed. Slider 77 has a rolling element (e.g. a ball, a skid or the like) that is not illustrated, and is engaged with (fitted into) X linear guide 75 in a slidable state with respect to X linear guide 75. Further, on each of the pair of opposed surfaces of X movable section 72, a coil unit 78 including coils is fixed so as to be opposed to magnetic unit 76 fixed to X guide 71. A pair of coil units 78 configure an X linear motor by the electromagnetic force (Lorentz force) drive method that drives X movable section 72 in the X-axis direction on X guide 71 owing to the electromagnetic interaction with a pair of magnetic units 76. The magnitude, the direction and the like of the electric current supplied to the coils of coil units 78 are controlled by the main controller that is not illustrated. Positional information of X movable section 72 in the X-axis direction is measured by a linear encoder system or an interferometer system, which is not illustrated, with high precision.

On the upper surface of each of the pair of X movable sections 72, one end (lower end) of a shaft 79 parallel to the Z-axis is fixed. As shown in FIG. 1, shaft 79 on the −Y side passes between the second air levitation unit 50 and the third air levitation unit 50 that configure the fourth air levitation unit row (or the third air levitation unit row, depending on the position of X movable section 72) and extends on the +Z side beyond the upper surfaces (gas jetting surfaces) of the respective air levitation units 50. And, shaft 79 on the +Y side passes between the sixth air levitation unit 50 and the seventh air levitation unit 50 that configure the fourth air levitation unit row (or the third air levitation unit row, depending on the position of X movable section 72). The other end (upper end) of each of a pair of shafts 79 is fixed to the lower surface of Y guide 73 (see FIG. 3). Consequently, Y guide 73 is placed higher than the upper surfaces of air levitation units 50. Y guide 73 is made up of a plate-shaped member width the Y-axis direction serving as its longitudinal direction, and has a magnetic unit, which is not illustrated, including a plurality of magnets disposed along the Y-axis direction inside thereof. In this case, as shown in FIG. 3, since Y guide 73 is placed above the plurality of air levitation units 50, the lower surface of Y guide 73 is supported by the air jetted from air levitation units 50, and accordingly, for example, the both ends of Y guide 73 in the Y-axis direction are prevented from bending downward because of the self weight, when the exposure processing or the like is performed on substrate P. Consequently, the stiffness to prevent the downward bending referred to above needs not be secured, which allows the reduction in weight of Y guide 73.

As shown in FIG. 3, X movable section 74 is made up of a box-shaped member having a space inside and being small in height direction size (thin), and on the lower surface of Y movable section 74, an opening section that allows shaft 79 to pass through is formed. Further, Y movable section 74 has an opening section on the side surfaces on the +Y side and the −Y side as well, and Y guide 73 is inserted into Y movable section 74 via the opening sections. Further, Y movable section 74 has noncontact thrust bearings, which are not illustrated, e.g., air bearings on the opposed surfaces opposed to Y guide 73, and Y movable section 74 is movable in the Y-axis direction above X guide 73 in a noncontact state. Since substrate holding frame 60 to hold substrate P is fixed to Y movable section 74, substrate holding frame 60 is in a noncontact state with respect to fixed-point stage 40 described previously and each of the plurality of air levitation units 50.

Further, Y movable section 74 has a coil unit including coils (the illustration is omitted) inside thereof. The coil unit configures a Y linear motor by the electromagnetic force drive method that drives Y movable section 74 in the Y-axis direction above Y guide 73 owing to the electromagnetic interaction with the magnetic unit that Y guide 73 has. The magnitude, the direction and the like of the electric current supplied to the coils of the coil unit are controlled by the main controller that is not illustrated. Positional information of Y movable section 74 in the Y-axis direction is measured by a linear encoder system or an interferometer system, which is not illustrated, with high precision. Incidentally, each of the X linear motor and the Y linear motor described above is either of the moving magnet type or the moving coil type, and the drive method is not limited to the Lorentz force drive method but can be other methods such as a variable magnetoresistance drive method. Further, as a drive device that drives the X movable section described above in the X-axis direction and a drive device that drives the Y movable section described above in the Y-axis direction, for example, a uniaxial drive device that includes a ball screw, a rack-and-pinion or the like can be used, or a device that tows the X movable section and the Y movable section in the X-axis direction and the I-axis direction, respectively, using a wire, a belt or the like.

Besides, exposure apparatus 10 has a surface position measuring system (the illustration is omitted) that measures surface position information (positional information in each of the Z-axis, θx and θy directions) of the surface (upper surface) of substrate P located directly under projection optical system PL. As the surface position measuring system, the one by an oblique incidence method as disclosed in, for example, U.S. Pat. No. 5,448,332 and the like can be used.

In liquid crystal exposure apparatus 10 (see FIG. 1) configured as described above, under control of the main controller that is not illustrated, mask M is loaded onto mask stage MST by a mask loader that is not illustrated and substrate P is loaded onto substrate stage device PST by a substrate loader that is not illustrated. After that, the main controller executes alignment measurement using an alignment detection system that is not illustrated, and after the alignment measurement is completed, an exposure operation by a step-and-scan method is performed.

FIGS. 6A to 6C show an example of an operation of substrate stage device PST during the exposure operation referred to above. Note that in the description below, the case of so-called two displays on a single substrate is described where one each of a rectangular shot area whose longitudinal direction is in the X-axis direction is set in an area on the +Y side and an area on the −Y side of substrate P. As shown in FIG. 6A, the exposure operation is performed from an area on the −Y side located on the −X side of substrate P toward an area on the −Y side located on the +X side of substrate P. On this operation, X movable section 72 (see the drawings such as FIG. 1) of drive unit 70 is driven in the −X direction on X guide 71, and thereby substrate P is driven in the −X direction (see a black arrow in FIG. 6A) with respect to exposure area IA and a scan operation (exposure operation) is performed on the area on the −Y side of substrate P. Subsequently, on substrate stage device PST, as sown in FIG. 6B, Y movable section 74 of drive unit 70 is driven in the −Y direction (see a white arrow in FIG. 6B) above Y guide 73, and thereby a step operation is performed. Note that in FIG. 6B, while the view is shown in which the step operation is performed in a state where substrate P is located in exposure area IA in order to facilitate understanding of the step operation, the step operation in practice is performed in a state where substrate P is located on the further −X side than the state shown in FIG. 6B. After that, as shown in FIG. 6C, X movable section 72 (see the drawings such as FIG. 1) of drive unit 70 is driven in the +X direction on X guide 71, and thereby substrate P is driven in the +X direction (see a black arrow in FIG. 6C) with respect to exposure area IA and a scan operation (exposure operation) is performed on the area on the +Y side of substrate P.

In the middle of the exposure operation by a step-and-scan method shown in FIGS. 6A to 6C, the main controller constantly measures positional information of substrate P within the XY plane and surface position information of a portion subject to exposure on the substrate surface using the interferometer system and the surface position measuring system, and appropriately controls the four Z-VCMs 38 based on the measurement values, thereby adjusting (positioning) the surface position (the position in the Z-axis direction and each of the θx and θy directions) of the section held by fixed-point stage 40, i.e. of the portion subject to exposure that is located directly under projection optical system PL such that the surface position is located within a depth of focus of projection optical system PL. Accordingly, in substrate stage device PST that liquid crystal exposure apparatus 10 of the present embodiment has, for example, even if the surface of substrate P has undulation or substrate P has error in thickness, the surface position of the portion subject to exposure of substrate P can surely be located within a depth of focus of projection optical system PL, which makes it possible to improve the exposure accuracy.

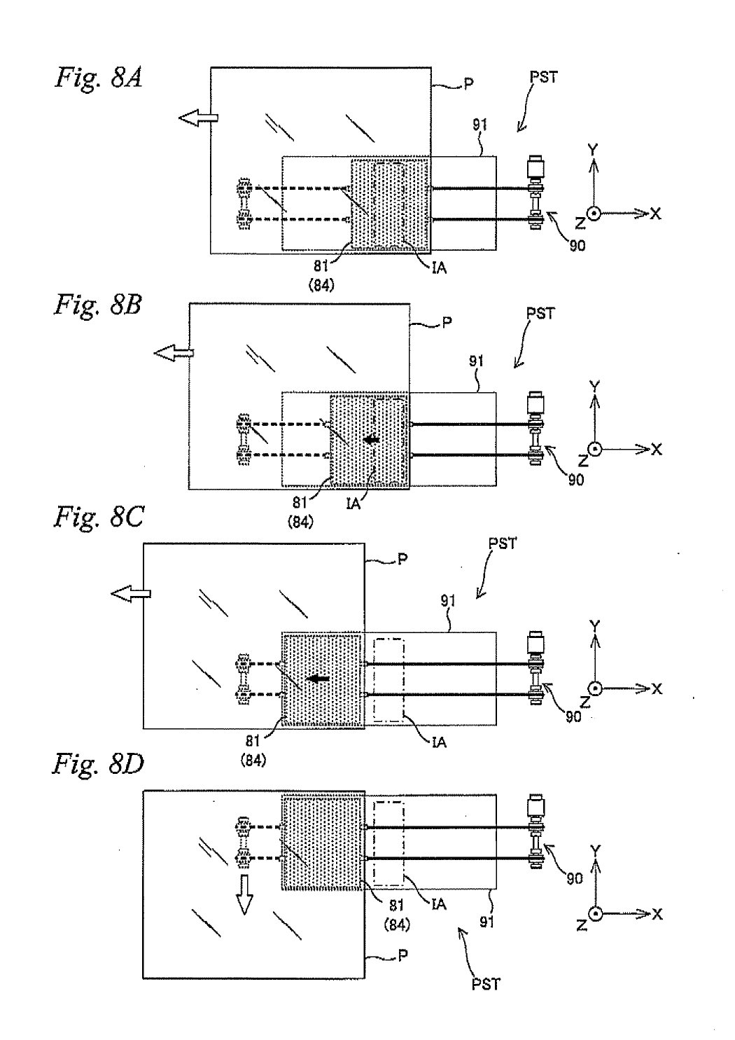

In this case, in substrate stage device PST, as described earlier, the position of chuck main body 81 (chuck member 84) of air chuck unit 80 of fixed-point stage 40 is variable in the X-axis direction. The main controller, which is not illustrated, controls the position in the X-axis direction of chuck main body 81 (chuck member 84) according to the position of substrate P during the exposure operation. In the description below, an example of an operation of air chuck unit 80 is specifically explained using FIGS. 7A to 8C. Incidentally, in FIGS. 7A to 8C, in order to prevent intricacy of the drawings, the illustration of the plurality of air levitation units 50, substrate holding frame 60, drive unit 70 and the like is omitted. Further, in the example described below, the exposure operation is performed from an area on the −X side located on the −Y side of substrate P, similarly to the example shown in FIGS. 6A to 6C.

In this case, in liquid crystal exposure apparatus 10, substrate P needs to be moved at a constant speed (to perform constant-velocity movement) in the X-axis direction during exposure. Therefore, prior to starting the exposure, the main controller causes in advance substrate P to be located on the +X side from exposure area IA by a distance that is the sum of a movement distance needed when substrate P is accelerated from a static state to a predetermined constant speed and a distance (so-called statically-determinate distance) needed when synchronizing substrate P and mask stage MST (FIG. 1). Further, in the state shown in FIG. 7A, the main controller controls drive unit 90 so as to cause chuck main body 81 (chuck member 84) to be located in an area on the +X side on guide plate 91, and at this position, causes chuck main body 81 (chuck member 84) to hold by adsorption an area in the vicinity of an −X side end of substrate P (an area including the −X side end of a shot area). The size of guide plate 91 in the X-axis direction is set such that chuck main body 81 (chuck member 84) can hold substrate P from below at the position where substrate P is static prior to exposure shown in FIG. 7A, that is, the position to which substrate P is withdrawn from exposure area IA.

When substrate P is accelerated in the −X direction for the exposure operation (see a white arrow in FIG. 7B) the main controller controls drive unit 90 based on the measurement values of a rotary encoder that is not illustrated, and accelerates chuck member 84 in the −X direction so as to follow substrate P (see a black arrow in FIG. 7B). In the state just before substrate P proceeds into exposure area IA as shown in FIG. 7B, substrate P performs constant-velocity movement and chuck member 84 also performs constant-velocity movement following substrate P. In this case, since substrate P and chuck member 84 are in a noncontact state, the position control of chuck main body 81 (chuck member 84) can be rough compared with that of substrate P. Consequently, any problems do not occur in particular when the position control of chuck member 84 is performed by open-loop control based on the number of rotations of pulley 93 or shaft 95 (see FIG. 4) as in the present embodiment.

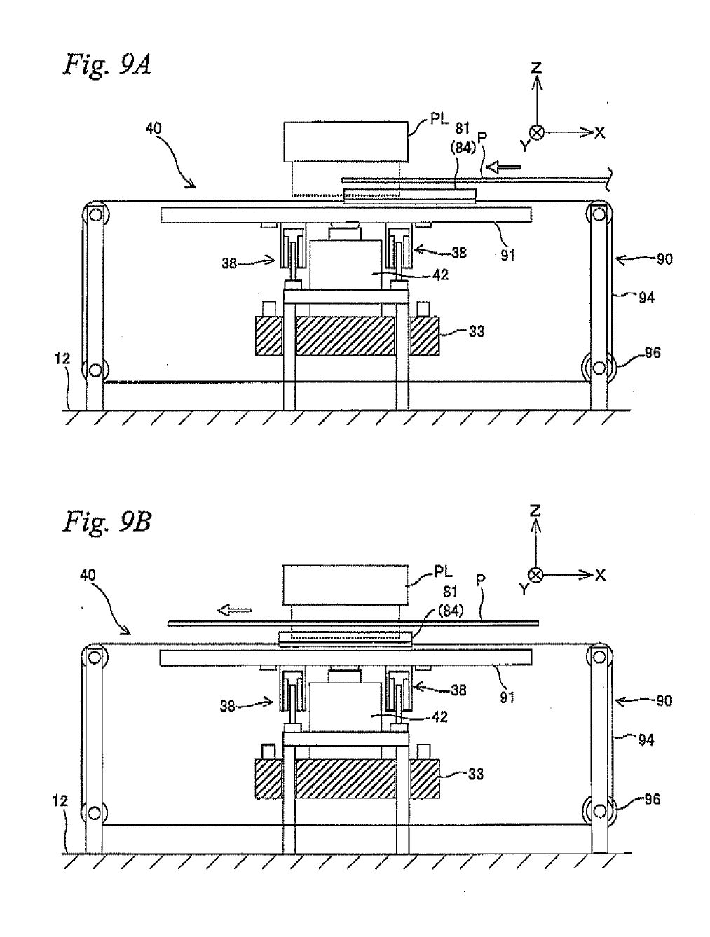

When substrate P is further driven in the −X direction from the state shown in FIG. 7B, substrate P (a shot area set on substrate P) proceeds into exposure area IA as shown in FIG. 7C, and the exposure operation is started. Further, chuck member 84 also proceeds into exposure area IA following substrate P (see FIG. 9A). Then, when chuck member 84 proceeds into exposure area IA, the main controller controls drive unit 90 to decelerate chuck member 84, and as shown in FIG. 7D, stops chuck member 84 in a state where the center of the upper surface of chuck main body 81 (chuck member 84) and the center of exposure area IA almost coincide (see FIG. 9B).

Note that, in order to stop chuck member 84 so as to make the center of chuck main body 81 coincide with the center of exposure area IA, it is necessary to decelerate chuck member 84 in a state where the center of chuck main body 81 is located slightly upstream (on the +X side) of the center of exposure area IA, as shown in FIG. 7C, but since the size in the X-axis direction of chuck main body 81 of the present embodiment is set longer than that of exposure area IA as described previously, chuck main body 81 can cover the entire area of exposure area IA at the time of starting deceleration. Consequently, chuck member 84 can surely hold by adsorption substrate P within exposure area IA when chuck main body 81 is decelerated with respect to substrate P.

After that, the main controller performs the exposure operation on substrate P while moving substrate P at a predetermined constant speed in the −X direction (chuck member 84 is stopped), as shown in FIG. 8A. As described previously, the surface position of the portion subject to exposure of substrate P, on which the exposure operation is performed within exposure area IA, is adjusted by fixed-point stage 40 that includes chuck main body 81.

Further, the main controller accelerates chuck member 84 in the −X direction just before the exposure operation on the shot area on the −Y side on substrate P is completed, and as shown in FIG. 83, performs constant-velocity drive in the X-axis direction of both substrate P and chuck member 84 in a state where chuck main body 81 holds an area in the vicinity of the +X side end (an area including the +X side end of a shot area) of substrate P.

After that, as shown in FIG. 8C, substrate P passes exposure area IA, and the exposure operation is completed. At this point, chuck main body 81 (chuck member 84) also passes exposure area IA, together with substrate P. After stopping substrate P and chuck main body 81 (chuck member 84), respectively, at positions withdrawn from exposure area IA, the main controller moves substrate P in the −Y direction as shown in FIG. 8D. Then, the main controller accelerates each of substrate P and chuck member 84 in the +X direction and performs the exposure operation on a shot area on the +Y side on substrate P in the procedure similar to the procedure shown in FIGS. 7A to 8C (however, the drive direction of each of substrate P and chuck member 84 is reversed).

In this case, if the position of chuck member 84 is fixed, then for example, when the tip of surface P proceeds into exposure area IA, the size of an area where substrate P and the upper surface of chuck main body 81 overlap, or more specifically, the load owing to the empty weight of substrate P acting on chuck main body 81 increases as substrate P moves in the scan direction. However, a configuration is employed in which chuck main body 81 holds substrate P by adsorption by a pressure balance (balance between the jet pressure and the suction pressure) of the gas between substrate P and chuck main body 81, and therefore, when the load owing to the empty weight of substrate P acting on chuck main body 81 varies, there is a possibility that the pressure balance described above is lost and the distance between substrate P and chuck main body 81 (a levitation amount of substrate P) varies. On the other hand, since chuck main body 81 in this embodiment holds substrate P beforehand outside exposure area IA prior to starting the exposure operation and chuck main body 81 proceeds into exposure area IA together with substrate P, the levitation amount of substrate P can be maintained constant.

Further, chuck member 84 is moved together with substrate P to the downstream side of the scanning direction with respect to exposure area IA as the exposure operation on a shot area on substrate P is completed, and therefore, also when the step operation (see FIG. 80) is performed and the exposure operation is performed on another shot area that is adjacent in the Y-axis direction, it is possible to cause chuck main body 81 to hold substrate P beforehand outside exposure area IA.

Further, when the surface position of substrate P is adjusted by fixed-point stage 40, hand 66 of substrate holding frame 60 is displaced in the Z-axis direction, following the operation (a movement in the Z-axis direction or a tilt operation) of substrate P. Accordingly, damage of substrate P, a shift (adsorption error) between hand 66 and substrate P, or the like is prevented. Incidentally, since the plurality of air levitation units 50 levitate substrate P higher compared with chuck main body 81 (chuck member 84), the air stiffness between substrate P and the plurality of air levitation units 50 is lower compared with the air stiffness between chuck main body 81 and substrate P. Consequently, substrate P can change its attitude without difficulty above the plurality of air levitation units 50. Further, if the amount of the attitude change of substrate P is large and hand 66 cannot follow substrate P, the adsorption error referred to above or the like can be avoided by the attitude of substrate holding frame 60 itself changing, since Y movable section 74 to which substrate holding frame 60 is fixed is supported by Y guide 73 in a noncontact manner. Incidentally, a configuration can also be employed in which the stiffness of the fastening section between Y guide 73 and X movable section 72 is lowered and the attitude of Y guide 73 as a whole changes together with substrate holding frame 60.

Further, in substrate stage device PST, substrate P that is substantially horizontally supported by levitation with the plurality of air levitation units 50 is held by substrate holding frame 60. Then, in substrate stage device PST, substrate holding frame 60 is driven by drive unit 70, and thereby substrate P is guided along a horizontal plane (the XY two-dimensional plane) and also the surface position of the portion subject to exposure of substrate P (a part of substrate P, within exposure area IA) is controlled by fixed-point stage 40 in a pinpoint manner. As described above, in substrate stage device PST, drive unit 70 (XY stage device) that is a device to guide substrate P along the XY plane, the plurality of air levitation units 50 that are devices to hold substrate P substantially horizontally and to position substrate P in the Z-axis direction, and fixed-point stage 40 (a Z/leveling stage device) are of different bodies that are independent from each other, and therefore, the weight (especially, the weight of its movable section) of substrate stage device PST can be considerably reduced, compared with a conventional stage device (e.g. refer to PCT International Publication No 2008/129762 (the corresponding U.S. Patent Application Publication No. 2010/0018950)) that drives a table member (substrate holder) used to hold substrate P with a good flatness degree, having an area size that is around the same as an area size of substrate P, in the Z-axis direction and the tilt direction respectively (in this case, the Z-leveling stage is also driven XY-two-dimensionally together with the substrate), on an XY two-dimensional stage device. To be specific, for example, in the case of using a large substrate one side of which is longer than 3 in, the total weight of the movable section amounts to nearly 10 t in the conventional stage device, whereas the total weight of the movable section (such as substrate holding frame 60, X movable section 72, X guide 73 and Y movable section 74) can be reduced to around several hundreds kg in substrate stage device PST of the present embodiment. Consequently, for example, each of the X linear motor used to drive X movable section 72 and the Y linear motor used to drive Y movable section 74 can be the linear motor with small outputs, which makes it possible to reduce the running cost. Further, the infrastructure such as power-supply facility can be provided without difficulty. Further, the initial cost can also be reduced because the outputs of the linear motors can be small.

Further, in drive unit 70, Y movable section 74 that holds substrate holding frame 60 is supported by Y guide 73 in a noncontact manner, and substrate P is guided along the XY plane, and therefore, there is little risk that the vibration (disturbance) in the Z-axis direction transmitted via the air bearings from the side of surface plate 12 installed on floor surface F adversely affects control of substrate holding frame 60. Consequently, the attitude of substrate P becomes stable and the exposure accuracy is improved.

Further, Y movable section 74 of drive unit 70 is supported by Y guide 73 in a noncontact state and dust is prevented from being generated, and therefore, although Y guide 73 and Y movable section 74 are placed above the upper surfaces (gas jetting surfaces) of the plurality of air levitation units 50, the exposure processing of substrate P is not affected. Meanwhile, X guide 71 and X movable section 72 are placed below air levitation units 50, and therefore, even if dust is generated, the possibility that dust affects the exposure processing is low. In this case, however, it is also possible that X movable section 72 is supported in a noncontact state with respect to X guide 71 so as to be movable in the X-axis direction, using, for example, air bearings or the like.

Further, weight canceller 42 of fixed-point stage 40 is mounted on Y beam 33 that is separated from surface plate 12 in terms of vibration, and therefore, for example, the reaction force of the drive force, vibration, or the like that is generated when substrate holding frame 60 (substrate P) is driven using drive unit 70 is not transmitted to weight canceller 42. Consequently, control of the position of chuck main body 81 (chuck member 84) (i.e. the surface position of the portion subject to exposure of substrate P) using Z-VCMs 38 can be performed with high precision. Further, of the four Z-VCMs 38 that drive chuck main body 81 (chuck member 84), Z stators 47 are fixed to base frame 85 that is noncontact with Y beam 33, and therefore the reaction force of the drive force generated when chuck main body 81 (chuck member 84) is driven is not transmitted to weight canceller 42. Consequently, the position of chuck main body 81 (chuck member 84) can be controlled with high precision.

Further, positional information of substrate holding frame 60 is measured with the interferometer system that uses movable mirrors 62x and 62y that are fixed to substrate frame 60, or more specifically, are placed close to substrate P that is subject to final positioning control, and therefore, the stiffness between the control subject (substrate P) and the measurement points can be maintained high. More specifically, since the substrate whose final position should be known and the measurement points can be regarded as being integrated, the measurement accuracy is improved. Further, the positional information of substrate holding frame 60 is directly measured, and therefore, even if a linear motion error occurs in X movable section 72 and Y movable section 74, the measurement results are hard to be affected. Incidentally, it is also possible that the positional information of substrate holding frame 60 is measured by a measurement system other than the interferometer system, for example, an encoder or the like.

Further, in substrate stage device PST, a configuration is employed in which the plurality of air levitation units 50, fixed-point stage 40 and drive unit 70 are placed side by side in a planar manner on surface plate 12, and therefore, the assembly, adjustment, maintenance and the like can be performed without difficulty. Further, the members are small in number and also the respective members are lightweight, which facilitates the transportation.

### Second Embodiment

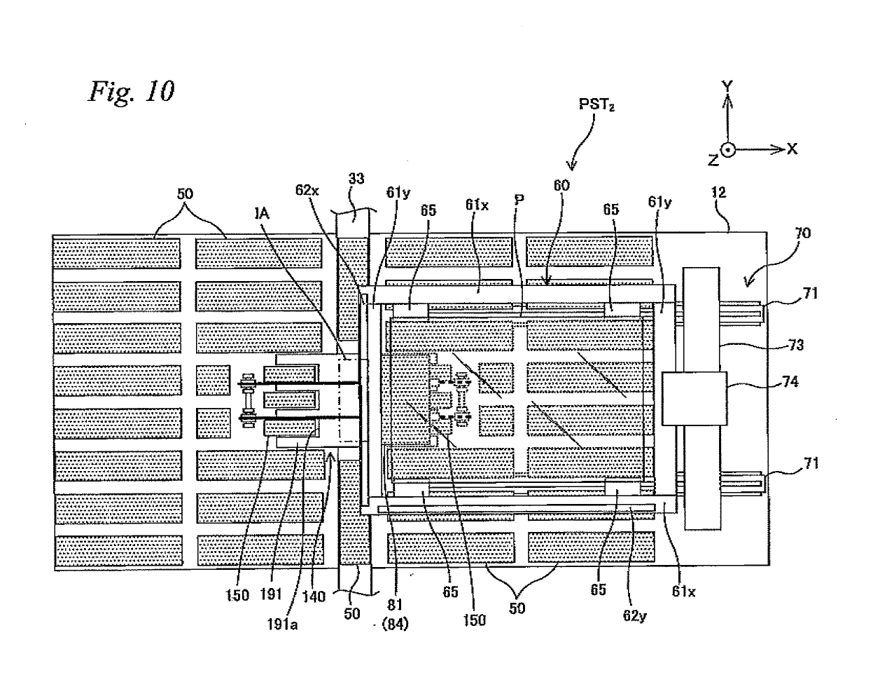

Next, a liquid crystal exposure apparatus of a second embodiment is described, referring to FIGS. 10 to 12C. Since the liquid crystal exposure apparatus of the present second embodiment has a configuration similar to the configuration of liquid crystal exposure apparatus 10 of the first embodiment except that a configuration of a substrate stage device that holds substrate P is different, only the configuration of the substrate stage device is described below. Here, from the viewpoint of preventing redundant description, members which have functions similar to those in the first embodiment are denoted by the same reference signs as the reference signs in the first embodiment and the description thereabout is omitted.

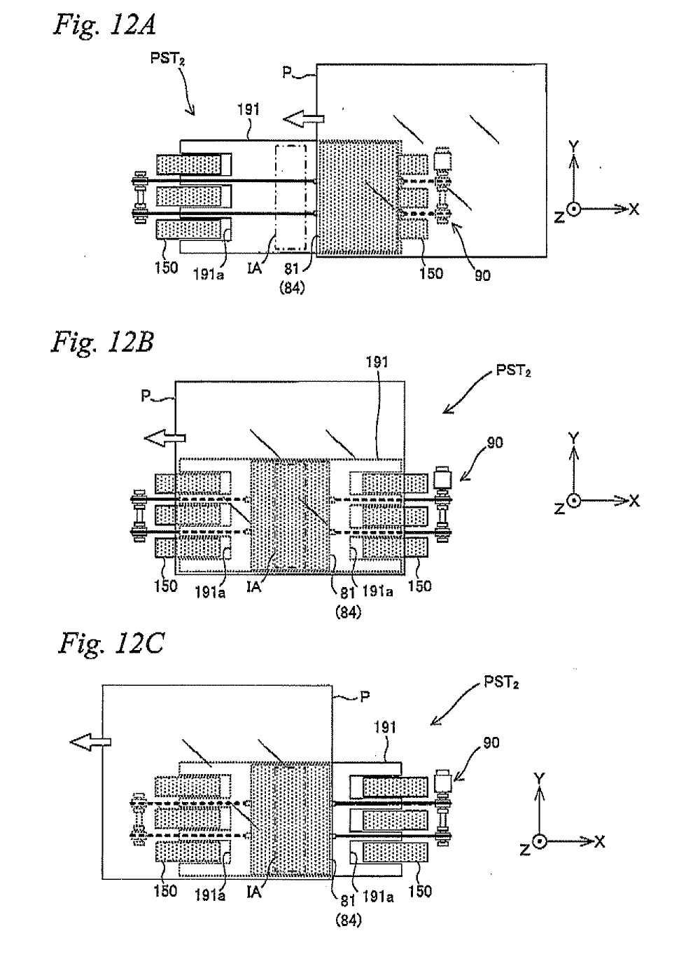

As shown in FIG. 10, a substrate stage device PST₂ related to the second embodiment has air levitation units 150 that support substrate P from below in a noncontact manner, in an area that overlaps with a movement range of chuck main body 81 (chuck member 84) of a fixed-point stage 140, which is a different point from the first embodiment described above. At each of the +X side end and the −X side end of a guide plate 191 of fixed-point stage 140, three cutouts 191a each having a rectangular shape in a planar view that is opened are formed, and inside the respective cutouts 191a, air levitation units 150 are housed (see FIG. 12B). The six air levitation units 150 housed inside cutouts 191a have functions similar to those of air levitation units 50 except that the area sizes of gas-jetting surfaces that are opposed to substrate P are small and their main sections 51 are vertically movable.

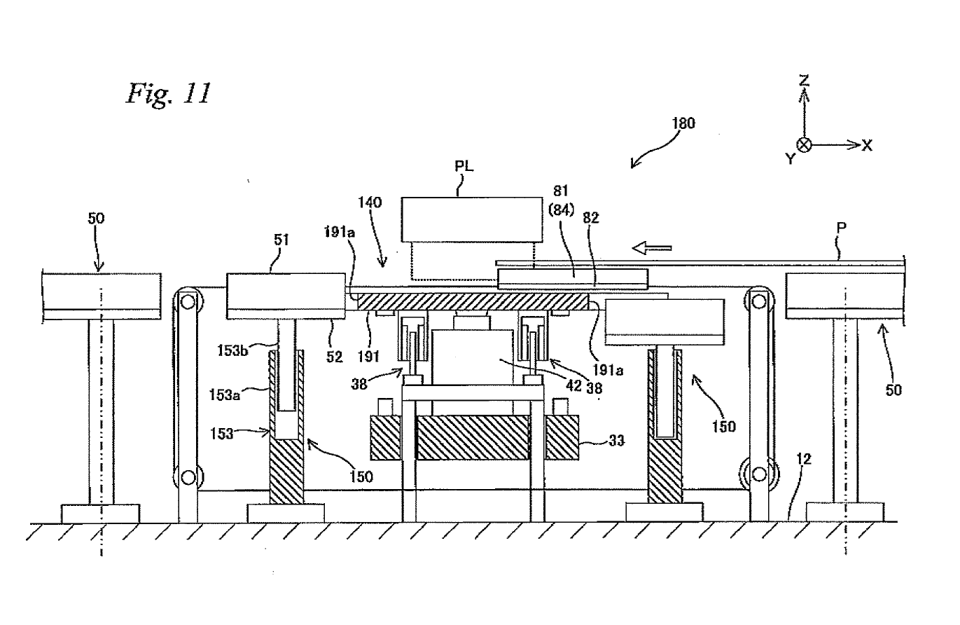

As shown in FIG. 11, leg section 153 of air levitation unit 150 includes a cylinder-like case 153a fixed on surface plate 12 and a shaft 153b one end of which is housed inside case 153a and the other end of which is fixed to support section 52 and which is driven in the Z-axis direction with respect to case 153a by a uniaxial, actuator that is not illustrated, for example, an air cylinder or the like. The upper surface of main section 51 can be located on the −Z side beyond the upper surface of guide plate 191 (the guide surface to guide horizontal movement of chuck main body 81 (chuck member 84)) by the shaft being driven in the −Z direction, like air levitation unit 150 on the +X side of Y beam 33 shown in FIG. 11. In this state, when chuck main body 81 and base 82 move on guide plate 191, their contact with main section 51 is prevented. Further, the upper surface of main section 51 can be located on the +Z side beyond the upper surface of guide plate 191 by shaft 153b being driven in the +Z direction, like air levitation unit 150 on the −X side of Y beam 33 shown in FIG. 11. Air levitation units 150 support substrate P by levitation in cooperation with the other air levitation units 50, at the position with which the upper surfaces of main sections 51 are placed coplanar with the upper surfaces of the plurality of air levitation units 50 (the position with which the distance to the lower surface of substrate P is, for example, 0.8 mm).

In an exposure operation using substrate stage device PST₂ of the present second embodiment, as shown in FIG. 12A, in the case where chuck main body 81 holds substrate P in an area on the +X side of exposure area TA, the main controller that is not illustrated controls the respective air levitation units 150 such that the upper surfaces of main sections 51 of the three air levitation units 150 placed on the +X side of Y beam 33 are located lower than the upper surface of guide plate 191, as shown in FIG. 11. On the other hand, the three air levitation units 150 placed on the −X side of Y beam 33 are controlled by the main controller such that the upper surfaces of the respective main sections 51 are placed coplanar with the upper surface of the other air levitation units 50, as shown in FIG. 11.

After that, similarly to the first embodiment described above, while driving substrate P in the −X direction at a constant speed, the main controller performs the exposure operation on substrate P within exposure area IA. Further, as shown in FIG. 12B, during the exposure operation, chuck main body 81 (chuck member 84) is stopped directly under exposure area IA, similarly to the first embodiment described above. The three air levitation units 150 placed on the −X side of Y beam 33 support an area of substrate P including the −X side end in a noncontact manner, and thereby the downward beading (flexure) of substrate P owing to the self weight is restrained. Further, in the state shown in FIG. 12B, the main controller controls each of the three air levitation units 150 placed on the +X side of Y beam 33 such that the upper surfaces of their main sections 51 are placed coplanar with the upper surface of the other air levitation units 50. The three air levitation units 150 placed on the +X side of Y beam 33 support an area of substrate P including the +X side end in a noncontact manner, and thereby the downward bending (flexure) of substrate P owing to the self weight is restrained.

Further, when the exposure operation proceeds and substrate P is further driven in the −X direction, chuck main body 81 is driven in the −X direction together with substrate P in a state holding an area, in the vicinity of the +X side end, of substrate P, similarly to the first embodiment described above, as shown in FIG. 12C. Therefore, the main controller controls each of the three air levitation units 150 placed on the −X side of X beam 33 to prevent chuck main body 81 (chuck member 84) and air levitation units 150 from coming in contact, and drives their main sections 51 in the −Z direction.

In substrate stage device PST₂ related to the second embodiment described above, the lower surface of substrate P is supported in a noncontact manner, on the +X side and/or the −X side of exposure area IA, by the plurality of air levitation units 150 placed inside cutouts 191a formed at guide plate 191, and therefore, the flexure owing to the self weight is restrained. Further, since each of the plurality of air levitation units 150 is withdrawn from the movement course of chuck main body 81 (chuck member 84) by main section 51 vertically moving, the plurality of air levitation units 150 do not block movement of chuck main body 81 (chuck member 84).

### Third Embodiment

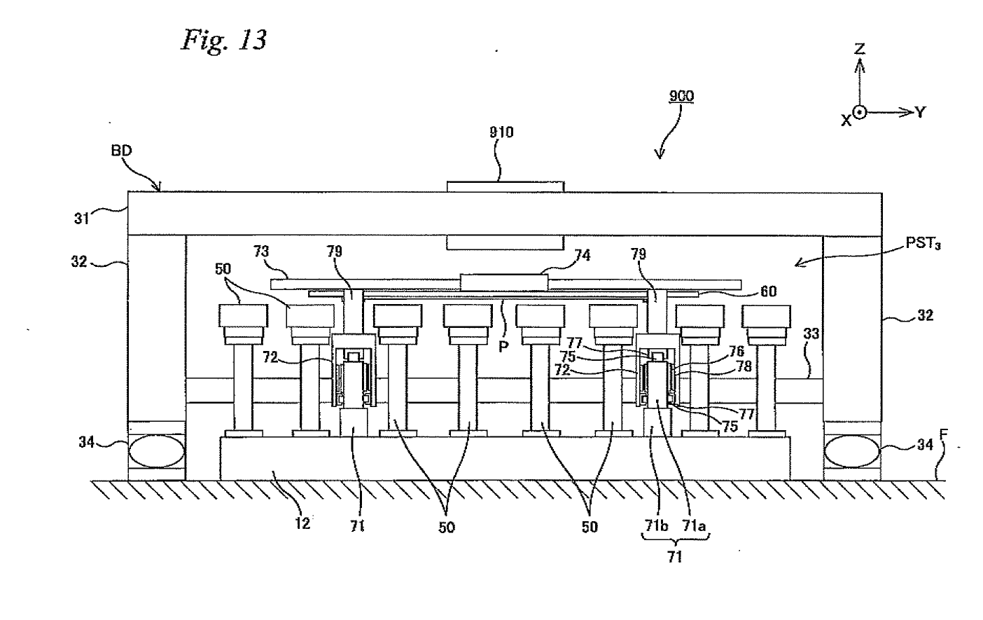

Next, a third embodiment is described. While the substrate stage devices related to the first and second embodiment are arranged in the liquid crystal exposure apparatus, a substrate stage device PST₃ related to the third embodiment is arranged in a substrate inspecting apparatus 900, as shown in FIG. 13.

Substrate inspecting apparatus 900 has a photographic unit 910 that is supported by body BD. Photographic unit 910 has a photographic optical system that includes, for example, an image sensor such as a CCD (Charge-Coupled Device), a lens and the like which are not illustrated, and photographs the surface of substrate P placed directly under (on the −Z side of) photographic unit 910. The outputs from photographic unit 910 (image data of the surface of substrate P) are output to an external device that is not illustrated, and inspection (e.g. detection of defects of patterns, or particles and the like) of substrate P is performed based on the image data. Note that the configuration of substrate stage device PST₉ that substrate inspecting apparatus 900 has is the same as that of substrate stage device PST₁ of the first embodiment described above (see FIG. 1). When inspection of substrate P is performed, the main controller adjusts the surface position of a portion subject to inspection (a portion directly under photographic unit 910) of substrate P using fixed-point stage 40 (see FIG. 2) such that the surface position is located within a depth of focus of the photographic optical system that photographic unit 910 has. Consequently, clear image data of substrate P can be obtained. Further, since the positioning of substrate P can be performed at a high speed and with high precision, the inspection efficiency of substrate P is improved. Incidentally, as the substrate stage device of the substrate inspecting apparatus, the substrate stage device related to the second embodiment described above can be applied. Incidentally, in the third embodiment described above, while the case where inspecting apparatus 900 is based on the imaging method is shown as an example, the inspecting apparatus is not limited to being based on the imaging method but can be based on another method, diffraction/scattering detection, or scatterometry or the like.

Incidentally, in each of the embodiments above, while the position of the substrate within the XY plane is controlled at a high speed and with high precision using the substrate holding frame, the substrate holding frame does not necessarily have to be used in the case where each of the embodiments above is applied to an object processing apparatus in which the position of a substrate needs not to be controlled with high precision, and for example, it is also possible to make a plurality of air levitation units have a horizontal carriage function of the substrate using air.

Further, in each of the embodiments above, while the substrate is guided along the horizontal plane by the drive unit (XY two-dimensional stage) that drives the substrate in the orthogonal two axial directions which are the X-axis and the Y-axis directions, the drive unit should guide the substrate only in one axis direction as far as, for example, the exposure area on the substrate and the substrate are the same in width. Further, in each of the embodiments above, the substrate and the chuck main body move together in the scanning direction just before the exposure operation is completed (see FIGS. 8B and 8C), but in the case where the scanning direction is not reversed during exposure, for example, in the case where the step operation is not performed during exposure, it is also possible that the chuck main body continues to be stopped directly under the exposure area (see FIG. 8A). Further, in the second embodiment above, while, the plurality of air levitation units placed in the movement course of the chuck main body each have a configuration in which the main section vertically moves, this is not intended to be limiting, and for example, the plurality of air levitation units can be withdrawn from the movement course of the chuck main body, by moving in a horizontal direction.

Further, in each of the embodiments above, the plurality of air levitation units support the substrate by levitation so as to make the substrate parallel to the XY plane, but depending on a type of an object that is subject to support, the configuration of the device that levitates the object is not limited thereto, and for example, the object can be levitated by magnetism or static electricity. Similarly, for the chuck member of the fixed-point stage, depending on a type of an object that is subject to holding, a configuration of holding an object that is subject to holding by magnetism or static electricity can also be employed.

Incidentally, in each of the embodiments above, while only one chuck member is arranged, this is not intended to be limiting, and a plurality of chuck members can be arranged. For example, in the case of arranging two chuck members, the two chuck members are placed side by side in the scan direction (X-axis direction) of a substrate, and one of the chuck members is made to wait at the exposure position while the other of the chuck members is moved (pre-scanned) together with the substrate from the upstream side of the scanning direction toward the exposure position. Then, when the scanning direction is reversed, the other chuck members is made to wait at the exposure position and the one chuck member is moved (pre-scanned) together with the substrate from the upstream side of the scanning direction toward the exposure position. Or, in the case of arranging three chuck members, the three chuck members are placed side by side in the scan direction (X-axis direction) of a substrate, a central chuck member is constantly made to be located in the exposure area, and depending on the scanning direction, a predetermined one of the chuck members located on one side and the other side is moved (pre-scanned) together with the substrate from the upstream side of the scanning direction toward the exposure position.

Further, the size of each of the plurality of chuck members can be the same as that of the chuck member in each of the embodiments above, or can be different from that of the chuck member in each of the embodiments above, and especially, in the case where the size of each of the plurality of chuck members is smaller, the total size of the plurality of chuck members can be set to be substantially the same (to have substantially the same shape and substantially the same area size) as the size of the chuck member in each of the embodiments above. Further, a countermass (a reaction force canceller that utilizes the law of conservation of momentum) can be arranged at the chuck member.

Further, in each of the embodiments above, while the positional information of the substrate holding frame within the XY plane is obtained by the laser interferometer system that includes the laser interferometers that irradiate the movable mirrors arranged on the substrate holding frame with the measurement beams, the position measuring device of the substrate holding frame is not limited thereto, but for example, a two-dimensional encoder system can be used. In this case, for example, it is possible that scales are arranged at the substrate holding frame and the positional information of the substrate holding frame is obtained by heads fixed to the body or the like, or it is also possible that heads are arranged at the substrate holding frame and the positional information of the substrate holding frame is obtained using scales fixed, for example, to the body or the like.

Incidentally, in each of the embodiments above, it is also possible that the fixed-point stage displaces the area subject exposure (or the area subject to photographing) of the substrate only in the Z-axis direction out of the Z-axis direction and the θx and θx directions.

Further, in each of the embodiments above, while the substrate holding frame has an outer shape (contour) that is rectangular in a planar view and the opening section that is rectangular in a planar view, the shape of the member that holds the substrate is not limited thereto, and for example, the shape can appropriately be changed in accordance with the shape of an object that is subject to holding (e.g. when an object is discoidal, a holding member can also have a circular frame shape).

Incidentally, in each of the embodiments above, the substrate holding frame does not have to enclose the whole periphery of the substrate, and it is also possible that a part of the periphery is not enclosed. Further, a member to hold the substrate such as the substrate holding frame does not necessarily have to be used for substrate carriage. In this case, it is necessary to measure the position of the substrate itself, and the position of the substrate can be measured by, for example, an interferometer that irradiates a measurement beam on the side surface of the substrate that serves as a mirror surface. Or, it is also possible that a grating is formed on the front surface (or the rear surface) of the substrate and the position of the substrate is measured by an encoder equipped with a head that irradiates the grating with measurement light and receives diffraction light of the measurement light.

Further, the illumination light can be ultraviolet light, such as ArF excimer laser light (with a wavelength of 193 nm) and KrF excimer laser light (with a wavelength of 248 nm), or vacuum ultraviolet light such as F₂ laser light (with a wavelength of 157 nm). Further, as the illumination light, a harmonic wave, which is obtained by amplifying a single-wavelength laser light in the infrared or visible range emitted by a DFB semiconductor laser or fiber laser with a fiber amplifier doped with, for example, erbium (or both erbium and ytterbium), and by converting the wavelength into ultraviolet light using a nonlinear optical crystal, can also be used. Further, solid state laser (with a wavelength of 355 nm, 266 nm) or the like can also be used.

Further, in each of the embodiments above, while the case has been described where projection optical system PL is the projection optical system by a multi-lens method that is equipped with a plurality of optical systems, the number of the projection optical systems is not limited thereto, but there should be one or more projection optical systems. Further, the projection optical system is not limited to the projection optical system by a multi-lens method, but can be a projection optical system using, for example, a large mirror of the Offner type, or the like. Further, while the case has been described where the projection optical system whose projection magnification is equal magnification is used as projection optical system PL in each of the embodiments above, this is not intended to be limiting, and the projection optical system can be either of a reduction system or a magnifying system.

Further, in each of the embodiments above, while the case has been described where the exposure apparatus is a scanning stepper, this is not intended to be limiting, and each of the embodiments above can also be applied to a projection exposure apparatus by a step-and-stitch method that synthesizes a shot area and a shot area. Further, each of the embodiments above can also be applied to an exposure apparatus by a proximity method that does not use any projection optical systems.

Incidentally, it is especially effective to apply the exposure apparatus in each of the embodiments above to an exposure apparatus that exposes a substrate with a size (which includes at least one of an outer diameter, a diagonal line and a side) not less than 500 mm, for example, a large substrate for a flat-panel display (FPD), such as a liquid crystal display element.

Further, the application of the exposure apparatus is not limited to the exposure apparatus for liquid crystal display elements in which a liquid crystal display element pattern is transferred onto a rectangular glass plate, but each of the embodiments above can also be widely applied, for example, to an exposure apparatus for manufacturing semiconductors, and an exposure apparatus for producing thin-film magnetic heads, micromachines, DNA chips, and the like. Further, each of the embodiments above can be applied not only to an exposure apparatus for producing microdevices such as semiconductor devices, but can also be applied to an exposure apparatus in which a circuit pattern is transferred onto a glass substrate, a silicon wafer or the like to produce a mask or a reticle used in a light exposure apparatus, an EUV exposure apparatus, an X-ray exposure apparatus, an electron-beam exposure apparatus, and the like. Incidentally, an object that is subject to exposure is not limited to a glass plate, but for example, can be another object such as a wafer, a ceramic substrate, a film member, or a mask blank.

Incidentally, the object processing apparatus related to each of the embodiments above can be applied not only to the exposure apparatus but also to, for example, an element manufacturing apparatus equipped with a functional liquid deposition device by an ink-jet method.

Incidentally, the disclosures of all publications, the PCT International Publications, the U.S. patent application publications and the U.S. patents that are cited in the description so far and are related to exposure apparatuses and the like are each incorporated herein by reference.

Device Manufacturing Method

A manufacturing method of a microdevice that uses the exposure apparatus in each of the embodiments above in a lithography process is described next. In the exposure apparatus in each of the embodiments above, a liquid crystal display element as a microdevice can be obtained by forming a predetermined pattern (such as a circuit pattern or an electrode pattern) on a plate (a glass substrate).

Pattern Forming Process

First of all, a so-called optical lithography process in which a pattern image is formed on a photosensitive substrate (such as a glass substrate coated with a resist) is executed using the exposure apparatus in each of the embodiments above. In this optical lithography process, a predetermined pattern that includes many electrodes and the like is formed on the photosensitive substrate. After that, the exposed substrate undergoes the respective processes such as a development process, an etching process and a resist removing process, and thereby the predetermined pattern is formed on the substrate.

Color Filter Forming Process

Next, a color filter in which many sets of three dots corresponding to R (Red), G (Green) and B (blue) are disposed in a matrix shape, or a color filter in which a plurality of sets of filters of three stripes of R, G and B are disposed in horizontal scanning line directions is formed.

Cell Assembling Process

Next, a liquid crystal panel (a liquid crystal cell) is assembled using the substrate having the predetermined pattern obtained in the pattern forming process, the color filter obtained in the color filter forming process, and the like. For example, a liquid crystal panel (a liquid crystal cell) is manufactured by injecting liquid crystal between the substrate having the predetermined pattern obtained in the pattern forming process and the color filter obtained in the color filter forming process.

Module Assembling Process

After that, a liquid crystal display element is completed by attaching respective components such as an electric circuit that causes a display operation of the assembled liquid crystal panel (liquid crystal cell) to be performed, and a backlight.

In this case, since exposure of the plate is performed with high throughput and high precision using the exposure apparatus in each of the embodiments above in the pattern forming process, the productivity of liquid crystal display elements can be improved as a consequence.

While the above-described embodiments of the present invention are the presently preferred embodiments thereof, those skilled in the art of lithography systems will readily recognize that numerous additions, modifications, and substitutions may be made to the above-described embodiments without departing from the spirit and scope thereof. It is intended that all such modifications, additions, and substitutions fall within the scope of the present invention, which is best defined by the claims appended below.

What is claimed is:

1. An object processing apparatus, comprising:
an object driving device that drives a tabular object placed along a predetermined two-dimensional plane that is parallel to a horizontal plane, in at least one axis direction within the two-dimensional plane;
an executing device that, with respect to the object that is driven at a constant speed by the object driving device, executes predetermined processing on a portion subject to processing of a surface of the object, within a predetermined area in a movement course of the object;
an adjustment device that includes a holding member having a holding surface smaller than an area size of the object, holds a part of the object from below in a noncontact state using the holding member, and adjusts a position of the object in a direction intersecting the two-dimensional plane; and
a drive device that drives the holding member in the one axis direction while adjusting a position of the holding member according to a position of the object with respect to the predetermined area.

2. The object processing apparatus according to claim 1, wherein
before the predetermined processing is performed on the object, the holding member holds in advance an area that includes a front end of the portion subject to processing of the object, at a position located upstream of the predetermined area in a movement direction of the object, and when the object is driven for the predetermined processing, the holding member moves together with the object in the one axis direction.

3. The object processing apparatus according to claim 2, wherein
a size of the holding surface is shorter than that of the portion subject to processing in the one axis direction, and
the drive device stops the holding member at a position that corresponds to the predetermined area while the predetermined processing is performed on the object.

4. The object processing apparatus according to claim wherein
a size of the holding surface is longer than that of the predetermined area in the one axis direction.

5. The object processing apparatus according to claim 3, wherein
before the predetermined processing on the object is completed, the holding member is accelerated toward a downstream side in the movement direction of the object by the drive device, and the holding member moves together with the object in the one axis direction in a state holding an area that includes a rear end of the portion subject to processing of the object.

6. The object processing apparatus according to claim wherein
the adjustment device holds the object in a noncontact manner by jetting a gas from the holding surface of the holding member to the object and suctioning a gas between the holding surface and the object.

7. The object processing apparatus according to claim 6, wherein
the adjustment device causes at least one of a pressure and a flow rate of the gas between the object and the holding surface to be variable such that a distance between the object and the holding surface is constant.

8. The object processing apparatus according to claim 1, wherein
the adjustment device has an actuator that drives the holding member in the direction intersecting the two-dimensional plane.

9. The object processing apparatus according to claim 8, wherein
the adjustment device further includes a support member that supports the holding member, and
the actuator includes a mover arranged at the support member and a stator arranged at a member that is separated, in terms of vibration, from a measurement member that measures positional information of the holding member.

10. The object processing apparatus according to claim 1, wherein
the adjustment device has a weight cancelling device that cancels a weight of the object.

11. The object processing apparatus according to claim 1, further comprising:
an upstream-side support device that supports the object from below in a noncontact manner, within an area that is located upstream of the predetermined area in the movement direction of the object and overlaps with a movement range of the holding member, wherein
in a case where the holding member is located upstream of the predetermined area in the movement direction of the object, the upstream-side support device is withdrawn from a movement course of the holding member.

12. The object processing apparatus according to claim wherein
the upstream-side support device supports the object in a noncontact manner by jetting a gas to the object.

13. The object processing apparatus according to claim 1, further comprising:
a downstream-side support device that supports the object from below in a noncontact manner, within an area that is located downstream of the predetermined area in the movement direction of the object and overlaps with the movement range of the holding member, wherein
in a case where the holding member is located downstream of the predetermined area in the movement direction of the object, the downstream-side support device is withdrawn from the movement course of the holding member.

14. The object processing apparatus according to claim 13, wherein
the downstream-side support device supports the object in a noncontact manner by jetting a gas to the object.

15. The object processing apparatus according to claim 1, further comprising:
a noncontact support device that supports the object from below in a noncontact manner by jetting a gas to the object, within a movable range where the object is movable, outside the movement range of the holding member.

16. The object processing apparatus according to claim 1, wherein
an end of the object is held by a movable body that is made up of a frame-shaped member arranged extending along the end of the object, and
the object driving device drives the movable body.

17. The object processing apparatus according to claim 1, wherein
the executing device includes an imaging device that picks up an image of a surface of the object to inspect the object.

18. The object processing apparatus according to claim wherein
the object is a substrate used for a display panel of a display device.

19. The object processing apparatus according to claim 1, wherein
the executing device is a pattern forming device that forms a predetermined pattern on the object by exposing the object with an energy beam.

20. A device manufacturing method, comprising:
exposing the object using the object processing apparatus according to claim 19; and
developing the exposed object.

21. An exposure apparatus that forms a predetermined pattern on an object by irradiating the object with an energy beam and exposing the object, the apparatus comprising:
an object driving device that drives a tabular object placed along a predetermined two-dimensional plane that is parallel to a horizontal plane, in at least one axis direction within the two-dimensional plane;
an exposure system that irradiates a surface of the object that is driven at a constant speed by the object driving device, with the energy beam in a movement course of the object;
an adjustment device that includes a holding member haying a holding surface smaller than an area site of the object, holds a part of the object from below in a noncontact state using the holding member, and adjusts a position of the object in a direction intersecting the two-dimensional plane; and
a drive device that drives the holding member in the one axis direction according to a position of the object with respect to an irradiation area of the energy beam by the exposure system.

22. The exposure apparatus according to claim 21, wherein
a size of the holding surface is shorter than that of an area subject to exposure on the object in the one axis direction, and
the drive device stops the holding member at a position that corresponds to the irradiation area while the irradiation is performed on the object.

23. The exposure apparatus according to claim 21, wherein
the size of the holding surface is longer than that of the irradiation area in the one axis direction.

24. The exposure apparatus according to claim 21, wherein
the adjustment device holds the object in a noncontact manner by jetting a gas from the holding surface of the holding member to the object and suctioning a gas between the holding surface and the object.

25. The exposure apparatus according to claim 24, wherein
the adjustment device causes at least one of a pressure and a flow rate of the gas between the object and the holding surface to be variable such that a distance between the object and the holding surface is constant.

26. The exposure apparatus according to claim 21, wherein
the adjustment device has an actuator that drives the holding member in the direction intersecting the two-dimensional plane.

27. The exposure apparatus according to claim 26, wherein
the adjustment device further includes a support member that supports the holding member, and
the actuator includes a mover arranged at the support member and a stator arranged at a member that is separated, in terms of vibration, from a measurement member that measures positional information of the holding member.

28. The exposure apparatus according to claim 21, wherein
the adjustment device has a weight cancelling device that cancels a weight of the object.

29. The exposure apparatus according to claim 21, further comprising:
an upstream-side support device that supports the object from below in a noncontact manner, within an area that is located upstream of the irradiation area of the energy beam in a movement direction of the object and overlaps with a movement range of the holding member, wherein
in a case where the holding member is located upstream of the irradiation area in the movement direction of the object, the upstream-side support device is withdrawn from a movement course of the holding member.

30. The exposure apparatus according to claim 29, wherein
the upstream-side support device supports the object in a noncontact manner by jetting a gas to the object.

31. The exposure apparatus according to claim 21, further comprising:
a downstream-side support device that supports the object from below in a noncontact manner, within an area that is located downstream of the irradiation area of the energy beam in the movement direction of the object and overlaps with the movement range of the holding member, wherein
in a case where the holding member is located downstream of the irradiation area in the movement direction of the object, the downstream-side support device is withdrawn from the movement course of the holding member.

32. The exposure apparatus according to claim 31, wherein
the downstream-side support device supports the object in a noncontact manner by jetting a gas to the object.

33. The exposure apparatus according to claim 21, further comprising:
a noncontact support device that supports the object from below in a noncontact manner by jetting a gas to the object, within a movable range where the object is movable, outside the movement range of the holding member.

34. The exposure apparatus according to claim 21, wherein
an end of the object is held by a movable body that is made up of a frame-shaped member arranged extending along the end of the object, and
the object driving device drives the movable body.

35. The exposure apparatus according to claim 21, wherein
the object is a substrate with a size not less than 500 mm.

36. A device manufacturing method, comprising:
exposing the object using the exposure apparatus according to claim 21; and
developing the exposed object.

37. A flat-panel display manufacturing method, comprising:
exposing a substrate for a flat-panel display using the exposure apparatus according to claim 21; and
developing the exposed substrate.

38. An exposure apparatus that forms a predetermined pattern on an object by exposing the object with an energy beam, the apparatus comprising:
an optical system that irradiates a partial area within a predetermined two-dimensional plane parallel to a horizontal plane, with the energy beam via the pattern;
a drive device that drives a tabular object placed along the two-dimensional plane, in at least one axis direction, within a predetermined area that includes the partial area within the two-dimensional plane; and
an adjustment device having a holding surface whose size is nearly the same as or smaller than the partial area, which holds a part of the object opposed to the holding surface, from below in a noncontact state and adjusts a position of the object in a direction intersecting the two-dimensional plane, when the object is driven by the drive device, and which moves in the one axis direction according to a position of the object with respect to the partial area.

39. The exposure apparatus according to claim 38, further comprising:
a noncontact support device that supports the object from below in a noncontact manner, with its support surface made to be opposed to the other area, excluding a section held by the adjustment device, of the object.

40. The exposure apparatus according to claim 38, further comprising:
a surface position measuring system that measures a distribution of surface positions, in a direction perpendicular to the two-dimensional plane, of an upper surface of the object within a part of the predetermined area.

41. The exposure apparatus according to claim 38, wherein
the object is a substrate with a size not less than 500 mm.

42. A device manufacturing method, comprising:
exposing the object using the exposure apparatus according to claim 38; and
developing the exposed object.

43. A flat-panel display manufacturing method, comprising:
exposing a substrate for a flat-panel display using the exposure apparatus according to claim 38; and
developing the exposed substrate.

44. An exposure method of forming a predetermined pattern on an object by exposing the object with an energy beam, the method comprising:
driving a tabular object placed along a predetermined two-dimensional plane parallel to a horizontal plane, in at least one axis direction, within a predetermined area that includes a partial area within the two-dimensional plane, the partial area being irradiated with the energy beam via the pattern by an optical system; and
holding, while changing a position in the one axis direction of a holding surface whose size is nearly the same as or smaller than the partial area, according to a position of the object with respect to the partial area, a section of the object opposed to the holding surface, from below the object in a noncontact state, and adjusting a position of the section in a direction intersecting the two-dimensional plane, when the object is driven.

45. The exposure method according to claim 44, further comprising:
supporting the other area, excluding the section, of the object from below in a noncontact manner.

46. A device manufacturing method, comprising:
exposing the object using the exposure method according to claim 44; and
developing the exposed object.
